(19) United States
(12) Patent Application Publication
(10) Pub. No.: US 2026/0245500 A1
(43) Pub. Date: Aug. 20, 2026

(54) DISPLAY DEVICE AND ELECTRONIC DEVICE INCLUDING THE SAME

(71) Applicant: Samsung Display Co., Ltd., Yongin-si (KR)

(72) Inventors: YONGHEE LEE, Yongin-si (KR); KYUNG-BAE KIM, Yongin-si (KR); DONGWOO KIM, Yongin-si (KR); YEONKYUNG KIM, Yongin-si (KR)

(73) Assignee: Samsung Display Co., Ltd., Yongin-si (KR)

(21) Appl. No.: 19/450,066

(22) Filed: Jan. 15, 2026

(30) Foreign Application Priority Data
Feb. 14, 2025 (KR) 10-2025-0019489

(51) Int. Cl. G09G 3/32

(52) U.S. Cl. CPC G09G 3/32; G09G 2300/0814

(57) ABSTRACT

Provided is a display device including a substrate including an N-well region and a P-well region spaced apart from the N-well region in a first direction, and a pixel including a first transistor in the P-well region of the substrate, the first transistor including a first drain region configured to receive an initialization voltage and a first source region connected to a pixel electrode of a light-emitting diode, a second transistor in the P-well region of the substrate, the second transistor including a second drain region sharing an impurity region with the first source region of the first transistor and a second source region connected to a driving transistor, and a third transistor in the N-well region of the substrate, the third transistor being configured to receive a data voltage and control the driving transistor.

### CROSS-REFERENCE TO RELATED APPLICATION

This application claims priority to Korean Patent Application No. 10-2025-0019489, filed on February 14, 2025, and all the benefits accruing therefrom under 35 U.S.C. §119, the content of which in its entirety is herein incorporated by reference.

### BACKGROUND

### FIELD

Embodiments of the present disclosure relate to a display device and an electronic device including the display device. More specifically, embodiments of the present disclosure relate to the display device that provides visual information and the electronic device including the display device.

### DESCRIPTION OF RELATED ART

A transistor in a display device may be used to perform various functions such as pixel driving and initialization. As a demand for high-resolution and large-screen display devices increases, there is a growing need for a higher-density arrangement of more pixels and transistors for controlling them.

In related technologies, various approaches have been proposed to more efficiently arrange a plurality of transistors including an initialization transistor. However, a method of mixing p-channel metal-oxide-semiconductor (PMOS) and n-channel metal-oxide-semiconductor (NMOS) transistors may increase wiring complexity and a difficulty of the manufacturing process. In particular, when an initialization transistor is implemented as a PMOS, there may be a risk of degraded current capacity and efficiency.

Accordingly, there is a need for a technology that arranges the initialization transistor as an NMOS to optimize current capacity, reduce wiring complexity, and achieve efficient transistor arrangement in high-integration display device designs.

### SUMMARY

One or more embodiments provide a display device with increased display quality.

One or more embodiments also provide an electronic device including the display device.

According to an aspect of one or more embodiments, there is provided a display device including a substrate including an N-well region and a P-well region spaced apart from the N-well region in a first direction, and a pixel including a first transistor in the P-well region of the substrate, the first transistor including a first drain region configured to receive an initialization voltage and a first source region connected to a pixel electrode of a light-emitting diode, a second transistor in the P-well region of the substrate, the second transistor including a second drain region sharing an impurity region with the first source region of the first transistor and a second source region connected to a driving transistor, and a third transistor in the N-well region of the substrate, the third transistor being configured to receive a data voltage and control the driving transistor.

The display device may further include a first channel region between the first drain region and the first source region, and a second channel region between the second drain region and the second source region.

The first transistor may further include a first gate electrode overlapping the first channel region in a second direction intersecting the first direction, and the second transistor may further include a second gate electrode overlapping the second channel region in the second direction.

The display device may further include a body pattern in the N-well region and configured to receive a power supply voltage.

The body pattern may be spaced apart from the third transistor in a third direction intersecting the first direction.

The display device may further include a guard ring between the P-well region and the N-well region and extending in a third direction intersecting the first direction.

According to another aspect of one or more embodiments, there is provided a display device including a substrate including a first N-well region, a second N-well region spaced apart from the first N-well region in a first direction, and a P-well region between the first N-well region and the second N-well region, a first pixel including a first-first transistor in the P-well region of the substrate, the first-first transistor including a first-first drain region configured to receive an initialization voltage and a first-first source region connected to a pixel electrode of a first light-emitting diode, and a second-first transistor in the first N-well region of the substrate, the second-first transistor being including to receive a data voltage is applied and control a first driving transistor, and a second pixel including a first-second transistor in the P-well region of the substrate, the first-second transistor including a first-second source region connected to a pixel electrode of a second light-emitting diode and a first-second drain region sharing an impurity region with the first-first drain region of the first-first transistor, and a second-second transistor in the second N-well region, the second-second transistor being configured to receive a data voltage and control a second driving transistor.

The display device my further include a first-first channel region between the first-first drain region and the first-first source region, and a first-second channel region between the first-second drain region and the first-second source region.

The first-first transistor may further include a first-first gate electrode overlapping the first-first channel region in a second direction intersecting the first direction, and the first-second transistor may further include a first-second gate electrode overlapping the first-second channel region in the second direction.

The display device may further include a first body pattern in the first N-well region and configured to receive a power supply voltage, and a second body pattern in the second N-well region and configured to receive a power supply voltage.

The first body pattern may be spaced apart from the second-first transistor in a third direction intersecting the first direction, and the second body pattern may be spaced apart from the second-second transistor in the third direction.

The display device may further include a first guard ring between the P-well region and the first N-well region and extending in a third direction intersecting the first direction, and a second guard ring between the P-well region and the second N-well region and extending in the third direction.

According to still another aspect of one or more embodiments, there is provide an electronic device including, a display device, and a processor configured to drive the display device, wherein the display device includes a substrate including an N-well region and a P-well region spaced apart from the N-well region in a first direction, and a pixel including a first transistor in the P-well region of the substrate, the first transistor including a first drain region configured to receive an initialization voltage and a first source region connected to a pixel electrode of a light-emitting diode, a second transistor in the P-well region of the substrate, the second transistor including a second drain region sharing an impurity region with the first source region of the first transistor and a second source region connected to a driving transistor, and a third transistor in the N-well region of the substrate, the third transistor being configured to receive a data voltage and control the driving transistor.

The electronic device may further include a body pattern in the N-well region and configured to receive a power supply voltage, and the body pattern may be spaced apart from the third transistor in a second direction intersecting the first direction.

The electronic device may further include a first channel region between the first drain region and the first source region, and a second channel region between the second drain region and the second source region.

The first transistor may further include a first gate electrode overlapping the first channel region in a second direction intersecting the first direction, and the second transistor may further include a second gate electrode overlapping the second channel region in the second direction.

The electronic device may further include a first guard ring between the P-well region and the N-well region and extending in a third direction intersecting the first direction.

The electronic device may further include a second guard ring on a side of the P-well region opposite to the first guard ring.

The electronic device may further include a fourth transistor and a fifth transistor in the N-well region and spaced apart from the third transistor in the first direction, a drain region of the fourth transistor and a source region of the fifth transistor may be shared.

The driving transistor may be disposed in the N-well region and between the first transistor and the third transistor.

### BRIEF DESCRIPTION OF DRAWINGS

Embodiments will be more clearly understood from the following detailed description taken in conjunction with the accompanying drawings in which:

FIG. 1 is a perspective view showing a display device according to one or more embodiments;

FIG. 2 is a block diagram showing components included in the display device of FIG. 1;

FIG. 3 is a cross-sectional view of the display panel of FIG. 2 according to one or more embodiments;

FIG. 4 is a circuit diagram of the pixel included of FIG. 2 according to one or more embodiments;

FIG. 5 is a plan view showing transistors disposed in the pixel of FIG. 4;

FIG. 6 is a cross-sectional view taken along line I-I’ of FIG. 5;

FIG. 7 is a circuit diagram of the pixel included of FIG. 2 according to one or more other embodiments;

FIG. 8 is a plan view showing transistors disposed in the pixel of FIG. 7;

FIG. 9 is a cross-sectional view taken along line II-II’ of FIG. 8;

FIG. 10 is a circuit diagram of the pixel included of FIG. 2 according to one or more other embodiments;

FIG. 11 is a plan view showing transistors disposed in the pixel of FIG. 10;

FIG. 12 is a cross-sectional view taken along line III-III’ of FIG. 11;

FIG. 13 is a block diagram showing an electronic device according to one or more embodiments; and

FIG. 14 is schematic diagrams of the electronic device of FIG. 13 according to one or more embodiments.

### DETAILED DESCRIPTION

Regarding embodiments of the present disclosure disclosed in this text, specific structural and functional descriptions are merely illustrative for a purpose of explaining the embodiments of the present disclosure, and the embodiments of the present disclosure may be implemented in various forms and should not be construed as limited to the embodiments described in.

Since the present disclosure may be subject to various changes and may have various forms, specific embodiments will be illustrated in the drawings and described in detail in the text. However, this is not intended to limit the present disclosure to a specific disclosed form, and should be understood to include all changes, equivalents, and substitutes included in the spirit and technical scope of the present disclosure.

Terms such as first, second, etc. may be used to describe various components, but the components should not be limited by the terms. The above terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments only and is not intended to be limiting of the present inventive concept. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, etc. is used to explain a relationship between components shown in the drawings. The terms are relative concepts and are explained based on the direction indicated in the drawings.

Unless otherwise defined, all terms (including technical and scientific terms) used herein have a same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2.

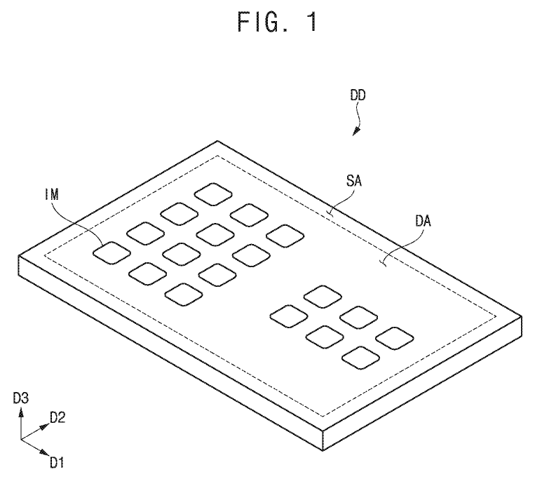

FIG. 1 is a perspective view showing a display device according to one or more embodiments.

Referring to FIG. 1, a display device DD may include a display area DA and a peripheral area SA. The display area DA may be at least partially surrounded by the peripheral area SA and/or disposed adjacent to the peripheral area SA.

The display area DA may be an area capable of generating light. The display area DA may be an area capable of adjusting a transmittance of light provided from an external light source to display an image. The peripheral area SA may be an area that does not display an image. However, embodiments are not limited thereto. For example, at least a portion of the peripheral area SA may also display an image.

The display area DA may display a plurality of images IM. Through the plurality of images IM, users may receive information from the display device DD.

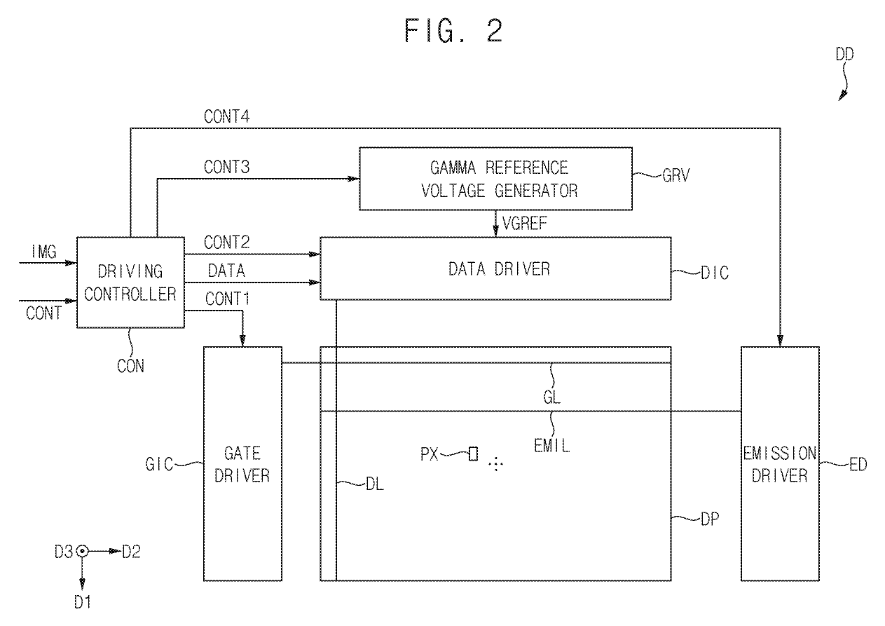

FIG. 2 is a block diagram showing components included in the display device of FIG. 1.

Referring to FIGS. 1 and 2, the display device DD may include a display panel DP and a display panel driver. The display panel driver may include a driving controller CON, a gate driver GIC, a gamma reference voltage generator GRV, a data driver DIC, and an emission driver ED.

The display panel DP may include the display area DA for displaying an image and the peripheral area SA disposed adjacent to the display area DA.

The display panel DP may include a plurality of gate lines GL, a plurality of data lines DL, a plurality of emission lines EMIL, and a plurality of pixels PX electrically connected to the gate lines GL, the data lines DL, and the emission lines EMIL, respectively.

The gate lines GL may extend from the gate driver GIC in a second direction D2 and may be spaced apart from each other in a first direction D1. The data lines DL may extend from the data driver DIC in the first direction D1 and may be spaced apart from each other in the second direction D2. The emission lines EMIL may extend from the emission driver ED in a direction opposite to the second direction D2 and may be spaced apart from each other in the first direction D1.

The driving controller CON may receive input image data IMG and input control signals CONT from an external device. For example, the input image data IMG may include red image data, green image data, and blue image data. The input image data IMG may include white image data. The input image data IMG may include magenta image data, yellow image data, and cyan image data. The input control signals CONT may include a master clock signal and a data enable signal. The input control signals CONT may further include a vertical synchronization signal and a horizontal synchronization signal.

The driving controller CON may generate a first control signal CONT1, a second control signal CONT2, a third control signal CONT3, a fourth control signal CONT4, and a data signal DATA based on the input image data IMG and the input control signals CONT.

The driving controller CON may generate the first control signal CONT1 to control an operation of the gate driver GIC based on the input control signals CONT, and may output the first control signal CONT1 to the gate driver GIC. The first control signal CONT1 may include a scan start signal and a gate clock signal, etc.

The driving controller CON may generate the second control signal CONT2 to control an operation of the data driver DIC based on the input control signals CONT, and may output the second control signal CONT2 to the data driver DIC. The second control signal CONT2 may include a horizontal start signal and a load signal, etc.

The driving controller CON may generate the data signal DATA based on the input image data IMG. The driving controller CON may output the data signal DATA to the data driver DIC.

The driving controller CON may generate the third control signal CONT3 to control an operation of the gamma reference voltage generator GRV based on the input control signals CONT, and may output the third control signal CONT3 to the gamma reference voltage generator GRV.

The driving controller CON may generate the fourth control signal CONT4 to control an operation of the emission driver ED based on the input control signals CONT, and may output the fourth control signal CONT4 to the emission driver ED.

The gate driver GIC may generate gate signals for driving the gate lines GL in response to the first control signal CONT1 received from the driving controller CON. The gate driver GIC may output the gate signals to the gate lines GL.

The gamma reference voltage generator GRV may generate a gamma reference voltage VGREF in response to the third control signal CONT3 received from the driving controller CON. The gamma reference voltage generator GRV may apply the gamma reference voltage VGREF to the data driver DIC. The gamma reference voltage VGREF may have a value corresponding to each data signal DATA.

For example, the gamma reference voltage generator GRV may be disposed within the driving controller CON or within the data driver DIC, or separate from the driving controller CON or within the data driver DIC.

The data driver DIC may receive the second control signal CONT2 and the data signal DATA from the driving controller CON, and may receive the gamma reference voltage VGREF from the gamma reference voltage generator GRV. The data driver DIC may convert the data signal DATA into an analog data voltage using the gamma reference voltage VGREF. The data driver DIC may output the data voltage to each of the data lines DL.

The emission driver ED may generate emission signals for driving the emission lines EMIL in response to the fourth control signal CONT4 received from the driving controller CON. The emission driver ED may output the emission signals to the emission lines EMIL.

In FIG. 2, for convenience of explanation, the gate driver GIC is shown as being spaced apart from the display panel DP in a direction opposite to the second direction D2, and the emission driver ED is shown as being spaced apart from the display panel DP in the second direction D2. However, the embodiments are not limited thereto. For example, the gate driver GIC and the emission driver ED may both be disposed on one side (e.g., a side spaced apart in the second direction D2) of the display panel DP. In another example, the gate driver GIC and the emission driver ED may both be disposed on opposite sides of the display panel DP from that illustrated in FIG. 2. In still another example, the gate driver GIC and the emission driver ED may be integrally formed.

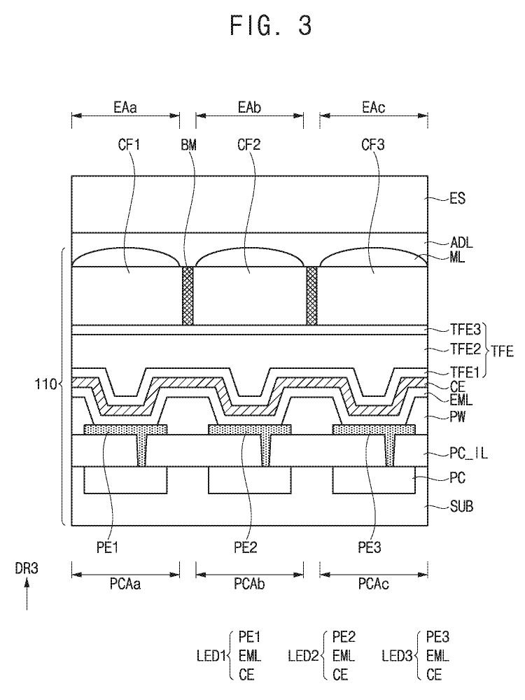

FIG. 3 is a cross-sectional view of the display panel of FIG. 2 according to one or more embodiments.

Referring to FIGS. 1, 2, and 3, the display device DD according to one or more embodiments may include the display panel DP and a sealing substrate ES. The display panel DP may include a substrate SUB, pixel circuit parts PC, a pixel circuit insulating layer PC_IL, a first light-emitting diode LED1, a second light-emitting diode LED2, a third light-emitting diode LED3, a partition wall PW, an encapsulation layer TFE, a first color filter layer CF1, a second color filter layer CF2, a third color filter layer CF3, a black matrix BM, and a lens layer.

The first light-emitting diode LED1 may include a first pixel electrode PE1, a light-emitting layer EML, and a common electrode CE. The second light-emitting diode LED2 may include a second pixel electrode PE2, the light-emitting layer EML, and the common electrode CE. The third light-emitting diode LED3 may include a third pixel electrode PE3, the light-emitting layer EML, and the common electrode CE.

The substrate SUB may include a first pixel circuit area PCAa, a second pixel circuit area PCAb, and a third pixel circuit area PCAc.

In one or more embodiments, the substrate SUB may include a silicon wafer substrate formed by a semiconductor process. The substrate SUB may serve as a support member for supporting other components of the display device DD. For example, the substrate SUB may include a semiconductor material such as group IV semiconductors, group III-V compound semiconductors, group II-VI compound semiconductors, etc. However, embodiments are not limited thereto.

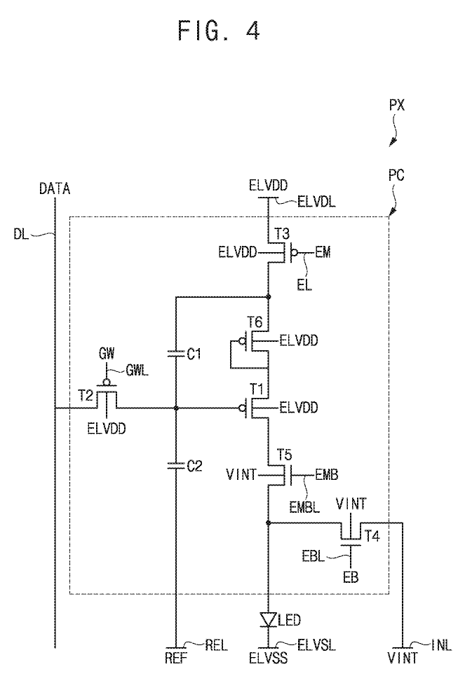

The pixel circuit parts PC may be disposed inside the substrate SUB. The pixel circuit parts PC may overlap the first, second, and third pixel circuit areas PCAa, PCAb, and PCAc, respectively, in the third direction DR3. Each of the pixel circuit parts PC may include various driving elements for driving the first, second, and third light-emitting diodes LED1, LED2, and LED3. For example, the pixel circuit parts PC may include at least one transistor and at least one capacitor formed by a semiconductor process. The pixel circuit parts PC may correspond to the pixel circuit parts PC shown in FIG. 4. For example, each pixel circuit part PC may include six transistors and two (or three) capacitors.

The pixel circuit insulating layer PC_IL may be disposed on the pixel circuit parts PC. The pixel circuit insulating layer PC_IL may prevent contact between the first, second, and third pixel electrodes PE1, PE2, and PE3 and the pixel circuit parts PC. The pixel circuit insulating layer PC_IL may include organic and/or inorganic materials. For example, the pixel circuit insulating layer PC_IL may include a plurality of layers formed of various insulating materials.

The first, second, and third pixel electrodes PE1, PE2, and PE3 may be disposed on the pixel circuit insulating layer PC_IL. The first pixel electrode PE1 may be disposed in a first emission area EAa that emits light of a first color, the second pixel electrode PE2 may be disposed in a second emission area EAb that emits light of a second color, and the third pixel electrode PE3 may be disposed in a third emission area EAc that emits light of a third color. For example, the first color may be red color, the second color may be green color, and the third color may be blue color, but embodiments are not limited thereto.

For example, the first emission area EAa may at least partially overlap the first pixel circuit area PCAa, the second emission area EAb may at least partially overlap the second pixel circuit area PCAb, and the third emission area EAc may at least partially overlap the third pixel circuit area PCAc in the third direction DR3.

The first pixel electrode PE1 may be electrically connected to one of the pixel circuit parts PC disposed in the first pixel circuit area PCAa through a contact hole penetrating the pixel circuit insulating layer PC_IL. The second pixel electrode PE2 may be electrically connected to one of the pixel circuit parts PC disposed in the second pixel circuit area PCAb through a contact hole penetrating the pixel circuit insulating layer PC_IL. The third pixel electrode PE3 may be electrically connected to one of the pixel circuit parts PC disposed in the third pixel circuit area PCAc through a contact hole penetrating the pixel circuit insulating layer PC_IL.

In FIG. 3, for convenience of explanation, the first, second, and third pixel electrodes PE1, PE2, and PE3 are illustrated as being directly connected to one of the pixel circuit parts PC, but the first, second, and third pixel electrodes PE1, PE2, and PE3 may be electrically connected to the pixel circuit parts PC through at least one conductive pattern.

The first, second, and third pixel electrodes PE1, PE2, and PE3 may include metals, alloys, metal nitrides, conductive metal oxides, transparent conductive materials, etc. The first, second, and third pixel electrodes PE1, PE2, and PE3 may include a same material and may be formed by a same process. For example, each of the first, second, and third pixel electrodes PE1, PE2, and PE3 may have a multilayer structure including indium tin oxide/silver/indium tin oxide (ITO/Ag/ITO). However, embodiments are not limited thereto. Each of the first, second, and third pixel electrodes PE1, PE2, and PE3 may be an anode electrode. As another example, each of the first, second, and third pixel electrodes PE1, PE2, and PE3 may be a reflective electrode. However, embodiments are not limited thereto.

The partition wall PW may be disposed on the pixel circuit insulating layer PC_IL. The partition wall PW may be provided on and/or cover an edge of each of the first, second, and third pixel electrodes PE1, PE2, and PE3. For example, the partition wall PW may be provided on and/or cover a side surface and a portion of an upper surface of each of the first, second, and third pixel electrodes PE1, PE2, and PE3. The partition wall PW may expose at least a portion of an upper surface of each of the first, second, and third pixel electrodes PE1, PE2, and PE3. For example, the partition wall PW may include inorganic materials such as silicon oxide, silicon nitride, silicon oxynitride, etc. These may be used alone or in combination with each other. As another example, the partition wall PW may include an organic material. In one or more embodiments, the partition wall PW may have a multilayer structure, but embodiments are not limited thereto.

The light-emitting layer EML may be disposed on the first, second, and third pixel electrodes PE1, PE2, and PE3 and the partition wall PW. The light-emitting layer EML may be a common layer commonly formed in the first, second, and third emission areas EAa, EAb, and EAc. For example, the light-emitting layer EML may extend continuously over an entirety of the first, second, and third emission areas EAa, EAb, and EAc. For example, the light-emitting layer EML may include a hole injection layer, a hole transport layer, an organic emission layer, an electron injection layer, and an electron transport layer. In one or more embodiments, the organic emission layer may include a light-emitting material that emits white light. For example, the white light may be light mixed with blue light, green light, and red light. As another example, the white light may be light mixed with blue light and yellow light. However, embodiments are not limited thereto.

The light-emitting layer EML may include a first emission layer overlapping the first emission area EAa in the third direction DR3 and including a light-emitting material that emits light of a first color (e.g., red light), a second emission layer overlapping the second emission area EAb in the third direction DR3 and including a light-emitting material that emits light of a second color (e.g., green light), and a third emission layer overlapping the third emission area EAc in the third direction DR3 and including a light-emitting material that emits light of a third color (e.g., blue light). In this case, the first, second, and third emission layers may be separated from each other, and the first, second, and third color filter layers CF1, CF2, and CF3 and the black matrix BM may be omitted.

The common electrode CE may be disposed on the light-emitting layer EML. The common electrode CE may be a common layer commonly formed in the first, second, and third emission areas EAa, EAb, and EAc. For example, the common electrode CE may extend continuously over an entirety of the first, second, and third emission areas EAa, EAb, and EAc. For example, the common electrode CE may include metals, alloys, metal nitrides, conductive metal oxides, transparent conductive materials, etc. These may be used alone or in combination with each other. The common electrode CE may be a cathode electrode. The common electrode CE may be a transmissive or semi-transmissive electrode.

Accordingly, the first pixel electrode PE1, the light-emitting layer EML, and the common electrode CE may be included in the first light-emitting diode LED1, the second pixel electrode PE2, the light-emitting layer EML, and the common electrode CE may be included in the second light-emitting diode LED2, and the third pixel electrode PE3, the light-emitting layer EML, and the common electrode CE may be included in the third light-emitting diode LED3. Each of the first, second, and third light-emitting diodes LED1, LED2, and LED3 may be electrically connected to the corresponding first, second, and third pixel circuit areas PCAa, PCAb, and PCAc.

The encapsulation layer TFE may be disposed on the common electrode CE. The encapsulation layer TFE may extend continuously over an entirety of the first, second, and third pixel circuit areas PCAa, PCAb, and PCAc. The encapsulation layer TFE may prevent impurities, moisture, etc. from penetrating into the first, second, and third light-emitting diodes LED1, LED2, and LED3 from an outside.

The encapsulation layer TFE may include at least one inorganic layer and at least one organic layer. For example, the encapsulation layer TFE may include a first inorganic encapsulation layer TFE1, an organic encapsulation layer TFE2 disposed on the first inorganic encapsulation layer TFE1, and a second inorganic encapsulation layer TFE3 disposed on the organic encapsulation layer TFE2 opposite to the first inorganic encapsulation layer TFE1. An upper surface of the organic encapsulation layer TFE2 facing the second inorganic encapsulation layer TFE3 may be substantially planar.

For example, the first and third inorganic encapsulation layers TFE1 and TFE3 may include silicon oxide, silicon nitride, silicon oxynitride, etc. These may be used alone or in combination with each other. The organic encapsulation layer TFE2 may include a polymer cured material such as polyacrylate.

The first, second, and third color filter layers CF1, CF2, and CF3 may be disposed on the encapsulation layer TFE. The first color filter layer CF1 may overlap the first emission area EAa, the second color filter layer CF2 may overlap the second emission area EAb, and the third color filter layer CF3 may overlap the third emission area EAc in the third direction DR3.

Each of the first, second, and third color filter layers CF1, CF2, and CF3 may selectively transmit light of a specific wavelength and absorb light of the remaining wavelengths. For example, the first color filter layer CF1 may transmit light of the first color (e.g., red light), the second color filter layer CF2 may transmit light of the second color (e.g., green light), and the third color filter layer CF3 may transmit light of the third color (e.g., blue light). Accordingly, the first emission area EAa may emit light of the first color, the second emission area EAb may emit light of the second color, and the third emission area EAc may emit light of the third color.

The black matrix BM may be disposed on the encapsulation layer TFE. The black matrix BM may be disposed between adjacent color filters of the first, second, and third color filter layers CF1, CF2, and CF3. For example, the black matrix BM may not overlap the first, second, and third emission areas EAa, EAb, and EAc in the third direction DR3. The black matrix BM may block light incident to the black matrix BM. Accordingly, the black matrix BM may prevent color mixing between the first, second, and third emission areas EAa, EAb, and EAc. For example, the black matrix BM may include organic and/or inorganic materials containing black pigment, black dye, etc.

The lens layer may be disposed on the first, second, and third color filter layers CF1, CF2, and CF3 and the black matrix BM. The lens layer may include a plurality of microlenses ML. The microlenses ML may improve light extraction efficiency. The microlenses ML may overlap the first, second, and third color filter layers CF1, CF2, and CF3, respectively, in the third direction DR3. The microlenses ML may have a predetermined refractive index with respect to visible light. For example, the microlenses ML may have a refractive index of about 1.5 to about 1.7 with respect to visible light. However, embodiments are not limited thereto. For example, each of the microlenses ML may have a convex cross-sectional shape.

The sealing substrate ES may be disposed on the lens layer. The sealing substrate ES may be attached to the display panel DP through an adhesive layer ADL. For example, the adhesive layer ADL may be between the sealing substrate ES and the lens layer. The sealing substrate ES may protect the display panel DP from moisture or gas intrusion. The sealing substrate ES may include a transparent insulating substrate. For example, the sealing substrate ES may include glass. For example, the adhesive layer ADL may include an optical clear adhesive (OCA), a pressure-sensitive adhesive (PSA), a photo-curable resin, a thermosetting resin, etc.

FIG. 4 is a circuit diagram of the pixel included of FIG. 2 according to one or more embodiments.

Referring to FIGS. 2, 3, and 4, the pixel PX may include one of the light-emitting diodes LED and one of the pixel circuit parts PC. For example, the pixel circuit parts PC may correspond to one of the pixel circuit parts PC shown in FIG. 3. The light-emitting diode LED may correspond to one of the first, second, and third light-emitting diodes LED1, LED2, and LED3 shown in FIG. 3. The pixel circuit parts PC may include a first transistor T1, a second transistor T2, a third transistor T3, a fourth transistor T4, a fifth transistor T5, a sixth transistor T6, a first capacitor C1, and a second capacitor C2.

In one or more embodiments, the first transistor T1, the second transistor T2, the third transistor T3, the fourth transistor T4, the fifth transistor T5, and the sixth transistor T6 may all be metal-oxide-semiconductor field-effect transistors (MOSFETs) formed by a semiconductor process.

In one or more embodiments, the first transistor T1, the second transistor T2, the third transistor T3, and the sixth transistor T6 may all be PMOS transistors. The fourth transistor T4 and the fifth transistor T5 may both be NMOS transistors. However, embodiments are not limited thereto.

The first transistor T1 may include a gate electrode, a first electrode, and a second electrode. The gate electrode of the first transistor T1 may be connected to a second electrode of the second transistor T2. The first electrode of the first transistor T1 may be connected to a second electrode of the sixth transistor T6. The second electrode of the first transistor T1 may be connected to a first electrode of the fifth transistor T5. The first transistor T1 may supply a driving current to the light-emitting diode LED. The first transistor T1 may be referred to as a driving transistor.

The first transistor T1 may further include a body electrode. A first power supply voltage ELVDD may be applied to the body electrode of the first transistor T1. For example, a driving voltage line ELVDL supplied with the first power supply voltage ELVDD may be connected to the body electrode of the first transistor T1. As another example, a power supply other than the first power supply voltage ELVDD may be applied to the body electrode of the first transistor T1.

The second transistor T2 may include a gate electrode, a first electrode, and a second electrode. A first gate signal line GWL that receives a first gate signal GW may be connected to the gate electrode of the second transistor T2. One of the data lines DL supplied with a data voltage DATA may be connected to the first electrode of the second transistor T2. The second electrode of the second transistor T2 may be connected to the gate electrode of the first transistor T1. The second transistor T2 may be referred to as a data writing transistor.

The second transistor T2 may further include a body electrode. The first power supply voltage ELVDD may be supplied to the body electrode of the second transistor T2. For example, the body electrode of the second transistor T2 may be connected to the driving voltage line ELVDL supplied with the first power supply voltage ELVDD. As another example, a power supply other than the first power supply voltage ELVDD may be applied to the body electrode of the second transistor T2.

The second transistor T2 may be turned on or off in response to the first gate signal GW. For example, when the first gate signal GW has an active level, the second transistor T2 may be turned on. In this case, the second transistor T2 may supply the data voltage DATA to the first transistor T1. When the first gate signal GW has an inactive level, the second transistor T2 may be turned off, thereby blocking a supply of the data voltage DATA.

The third transistor T3 may include a gate electrode, a first electrode, and a second electrode. A first emission control line EL that receives a first emission control signal EM may be connected to the gate electrode of the third transistor T3. The first electrode of the third transistor T3 may be connected to a driving voltage line ELVDL supplied with the first power supply voltage ELVDD. The second electrode of the third transistor T3 may be connected to the first electrode of the sixth transistor T6. The third transistor T3 may be referred to as an emission control transistor.

The third transistor T3 may further include a body electrode. The body electrode of the third transistor T3 may be supplied with the first power supply voltage ELVDD. For example, the body electrode of the third transistor T3 may be connected to the driving voltage line ELVDL supplied with ELVDD. As another example, a power supply other than ELVDD may be applied to the body electrode of the third transistor T3.

The third transistor T3 may be turned on or off in response to the first emission control signal EM. For example, when the first emission control signal EM has an active level, the third transistor T3 may be turned on, thereby supplying a driving current generated by the first transistor T1 to the anode electrode of the light-emitting diode LED. When the first emission control signal EM has an inactive level, the third transistor T3 may be turned off. In this case, the third transistor T3 may block the driving current generated by the first transistor T1.

The fourth transistor T4 may include a gate electrode, a first electrode, and a second electrode. A second gate signal line G that receives a second gate signal EB may be connected to the gate electrode of the fourth transistor T4. An initialization voltage line INL supplied with an initialization voltage VINT may be connected to the first electrode of the fourth transistor T4. The second electrode of the fourth transistor T4 may be connected to the second electrode of the first transistor T1. For example, the fourth transistor T4 may be electrically connected to the first transistor T1. The fourth transistor T4 may be referred to as an initialization transistor.

The fourth transistor T4 may further include a body electrode. The body electrode of the fourth transistor T4 may be supplied with the initialization voltage VINT. For example, the body electrode of the fourth transistor T4 may be connected to the initialization voltage line INL supplied with VINT. As another example, a power supply other than VINT may be applied to the body electrode.

The fourth transistor T4 may be turned on or off in response to the second gate signal EB. For example, when the second gate signal EB has an active level, the fourth transistor T4 may be turned on. In this case, the fourth transistor T4 may supply the initialization voltage VINT to the light-emitting diode LED. When the second gate signal EB has an inactive level, the fourth transistor T4 may be turned off. In this case, the fourth transistor T4 may block the initialization voltage VINT.

The fifth transistor T5 may include a gate electrode, a first electrode, and a second electrode. A second emission control line EMBL that receives a second emission control signal EMB may be connected to the gate electrode of the fifth transistor T5. The first electrode of the fifth transistor T5 may be connected to the first electrode of the first transistor T1. The second electrode of the fifth transistor T5 may be connected to the second electrode of the fourth transistor T4. The fifth transistor T5 may be referred to as an emission control transistor.

The fifth transistor T5 may further include a body electrode. The body electrode of the fifth transistor T5 may be supplied with the initialization voltage VINT. For example, the body electrode of the fifth transistor T5 may be connected to the initialization voltage line INL supplied with VINT. As another example, a power supply other than VINT may be applied to the body electrode.

The fifth transistor T5 may be turned on or off in response to the second emission control signal EMB. For example, when the second emission control signal EMB has an active level, the fifth transistor T5 may be turned on. In this case, the fifth transistor T5 may supply a driving current to the light-emitting diode LED. When the second emission control signal EMB has an inactive level, the fifth transistor T5 may be turned off. In this case, the fifth transistor T5 may block the driving current.

The sixth transistor T6 may include a gate electrode, a first electrode, and a second electrode. The gate electrode of the sixth transistor T6 may be connected to the first electrode of the first transistor T1. The first electrode of the sixth transistor T6 may be connected to the second electrode of the third transistor T3. The second electrode of the sixth transistor T6 may be connected to the first electrode of the first transistor T1. The sixth transistor T6 may be referred to as an emission control transistor.

The sixth transistor T6 may further include a body electrode. The body electrode of the sixth transistor T6 may be supplied with the first power supply voltage ELVDD. For example, the body electrode of the sixth transistor T6 may be connected to the driving voltage line ELVDL supplied with ELVDD. As another example, a power supply other than ELVDD may be applied to the body electrode.

The first capacitor C1 may include a first electrode and a second electrode. The first electrode of the first capacitor C1 may be connected to the second electrode of the third transistor T3. The second electrode of the first capacitor C1 may be connected to the gate electrode of the first transistor T1.

The second capacitor C2 may include a first electrode and a second electrode. A reference voltage line REL supplied with a reference voltage REF may be connected to the first electrode of the second capacitor C2. The second electrode of the second capacitor C2 may be connected to the gate electrode of the first transistor T1.

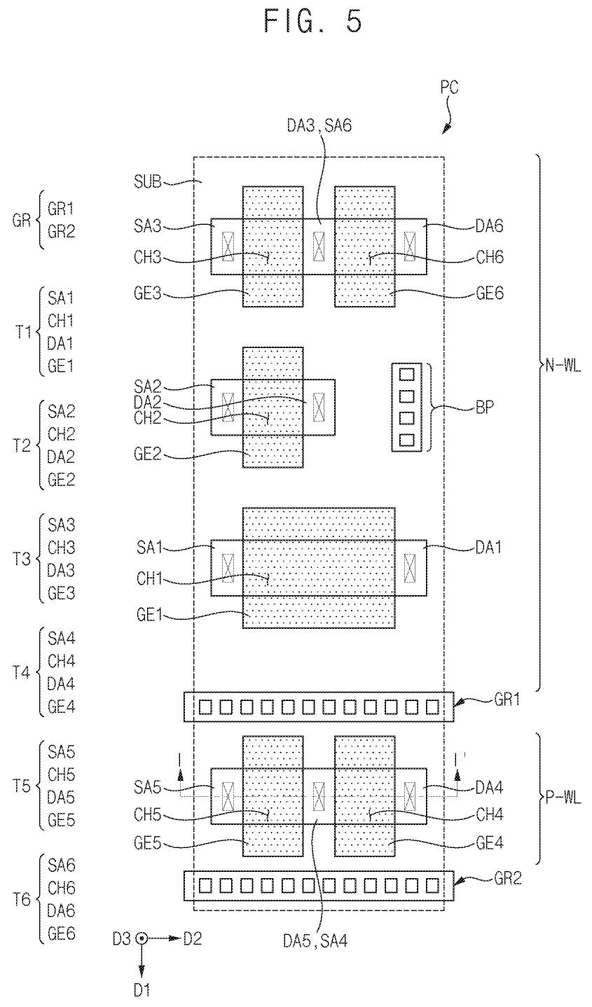

FIG. 5 is a plan view showing transistors disposed in the pixel of FIG. 4.

Referring to FIGS. 4 and 5, the substrate SUB of the pixel PX may include a P-well region P-WL and an N-well region N-WL. For example, the P-well region P-WL and the N-well region N-WL may be spaced apart from each other in a first direction D1.

The fourth transistor T4 and the fifth transistor T5 may be disposed in the P-well region P-WL. The first transistor T1, the second transistor T2, the third transistor T3, the sixth transistor T6, and body pattern BP may be disposed in the N-well region N-WL.

The P-well region P-WL may include the fourth transistor T4 and the fifth transistor T5. The N-well region N-WL may include the first transistor T1, the second transistor T2, the third transistor T3, the sixth transistor T6, and a body pattern BP.

The fourth transistor T4 may include a fourth drain region DA4, a fourth source region SA4, a fourth channel region CH4, and a fourth gate electrode GE4. The fourth drain region DA4 and the fourth source region SA4 may correspond to the first and second electrodes of the fourth transistor T4 shown in FIG. 4, respectively, and the fourth gate electrode GE4 may correspond to the gate electrode of the fourth transistor T4 shown in FIG. 4. The fourth drain region DA4 and the fourth source region SA4 may be doped with an N-type material and the fourth transistor T4 may be an NMOS transistor.

The fifth transistor T5 may include a fifth drain region DA5, a fifth source region SA5, a fifth channel region CH5, and a fifth gate electrode GE5. The fifth drain region DA5 and the fifth source region SA5 may correspond to the first and second electrodes of the fifth transistor T5 shown in FIG. 4, and the fifth gate electrode GE5 may correspond to the gate electrode of the fifth transistor T5 shown in FIG. 4. The fifth drain region DA5 and the fifth source region SA5 may be doped with an N-type material, and the fifth transistor T5 may be an NMOS transistor.

In one or more embodiments, the fourth source region SA4 of the fourth transistor T4 and the fifth drain region DA5 of the fifth transistor T5 may be shared. For example, the fourth source region SA4 and the fifth drain region DA5 may refer to a same region. Accordingly, the fourth transistor T4 and the fifth transistor T5 may share an impurity region and may be integrally formed in the second direction D2. However, embodiments are not limited thereto.

The first transistor T1 may include a first drain region DA1, a first source region SA1, a first channel region CH1, and a first gate electrode GE1. The first drain region DA1 and the first source region SA1 may correspond to the first and second electrodes of the first transistor T1 shown in FIG. 4, and the first gate electrode GE1 may correspond to the gate electrode of the first transistor T1 shown in FIG. 4. The first drain region DA1 and the first source region SA1 may be doped with a P-type material. For example, the first transistor T1 may be a PMOS transistor. Although the first transistor T1 is illustrated as having a shape extending in the second direction D2, embodiments are not limited thereto.

The second transistor T2 may include a second drain region DA2, a second source region SA2, a second channel region CH2, and a second gate electrode GE2. The second drain region DA2 and the second source region SA2 may correspond to the first and second electrodes of the second transistor T2 shown in FIG. 4, and the second gate electrode GE2 may correspond to the gate electrode of the second transistor T2 shown in FIG. 4. The second drain region DA2 and the second source region SA2 may be doped with a P-type material, and the second transistor T2 may be a PMOS transistor.

The body pattern BP may be a pattern to which the first power supply voltage (e.g., the first power supply voltage ELVDD of FIG. 4) is applied. The body pattern BP may apply the first power supply voltage ELVDD to the N-well region N-WL of the substrate SUB.

In one or more embodiments, the body pattern BP may be spaced apart from the second transistor T2 in the second direction D2. Since the body pattern BP is disposed adjacent to the second transistor T2, a transistor array may be more efficiently arranged.

The third transistor T3 may include a third drain region DA3, a third source region SA3, a third channel region CH3, and a third gate electrode GE3. The third drain region DA3 and the third source region SA3 may correspond to the first and second electrodes of the third transistor T3 shown in FIG. 4, and the third gate electrode GE3 may correspond to the gate electrode of the third transistor T3 shown in FIG. 4. The third drain region DA3 and the third source region SA3 may be doped with a P-type material, and the third transistor T3 may be a PMOS transistor.

The sixth transistor T6 may include a sixth drain region DA6, a sixth source region SA6, a sixth channel region CH6, and a sixth gate electrode GE6. The sixth drain region DA6 and the sixth source region SA6 may correspond to the first and second electrodes of the sixth transistor T6 shown in FIG. 4, and the sixth gate electrode GE6 may correspond to the gate electrode of the sixth transistor T6 shown in FIG. 4. The sixth drain region DA6 and the sixth source region SA6 may be doped with a P-type material, and the sixth transistor T6 may be a PMOS transistor.

In one or more embodiments, the third drain region DA3 of the third transistor T3 and the sixth source region SA6 of the sixth transistor T6 may be shared. For example, the third drain region DA3 and the sixth source region SA6 may refer to a same region. Accordingly, the third transistor T3 and the sixth transistor T6 may share an impurity region and may be integrally formed in the second direction D2. However, embodiments are not limited thereto. The third transistor T3 and the sixth transistor T6 may also be separately formed without sharing an impurity region.

A guard ring GR may be further disposed between the P-well region P-WL and the N-well region N-WL. The guard ring GR may serve as a boundary between the P-well region P-WL and the N-well region N-WL. In addition, the guard ring GR may prevent or reduce side effects such as leakage current or electric fields between the P-well region P-WL and the N-well region N-WL. The guard ring GR may include a first guard ring GR1 disposed between the P-well region P-WL and the N-well region N-WL, and a second guard ring GR2 spaced apart from the first guard ring GR1 in the first direction D1 with the P-well region P-WL interposed therebetween.

In one or more embodiments, the first guard ring GR1 may be disposed between the first transistor T1 and the fourth transistor T4. By disposing the first guard ring GR1, stability of an operation of the pixel PX may be ensured and reliability may be improved. For example, the guard ring GR may relieve or block an electric field generated during high-voltage driving, thereby improving operational stability of the first, second, third, fourth, fifth, and sixth transistors. In addition, the guard ring GR may block leakage current to reduce power loss in the circuit and prevent parasitic transistor effects.

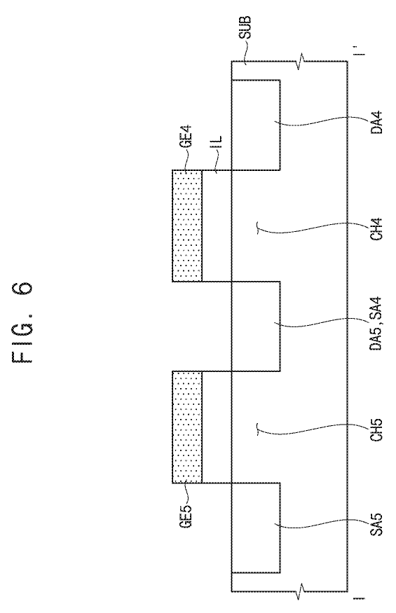

FIG. 6 is a cross-sectional view taken along line I-I’ of FIG. 5.

Referring to FIGS. 5 and 6, the fourth transistor T4 may include the fourth drain region DA4, the fourth source region SA4, the fourth channel region CH4, and the fourth gate electrode GE4. The fifth transistor T5 may include the fifth drain region DA5, the fifth source region SA5, the fifth channel region CH5, and the fifth gate electrode GE5.

The substrate SUB may include a semiconductor material. In one or more embodiments, the substrate SUB may be an N-type semiconductor substrate doped with N-type impurities or a P-type semiconductor substrate doped with P-type impurities. The substrate SUB of the cross-sectional portion along the I-I’ line shown in FIG. 6 may be a P-type semiconductor substrate doped with P-type impurities. For example, the fourth drain region DA4, the fourth source region SA4, the fifth drain region DA5, and the fifth source region SA5 may be doped as N-type on the P-type semiconductor substrate. Accordingly, each of the fourth transistor T4 and the fifth transistor T5 may be an NMOS transistor disposed on the P-type semiconductor substrate.

The fourth channel region CH4 may be defined between the fourth source region SA4 and the fourth drain region DA4 within the substrate SUB. The fifth channel region CH5 may be defined between the fifth source region SA5 and the fifth drain region DA5 within the substrate SUB. For example, each of the fourth channel region CH4 and the fifth channel region CH5 may include a same semiconductor material as the substrate SUB. A current may flow between the fourth drain region DA4 and the fourth source region SA4 through the fourth channel region CH4, and between the fifth drain region DA5 and the fifth source region SA5 through the fifth channel region CH5.

The fourth gate electrode GE4 may be disposed overlapping the fourth channel region CH4 in a plan view on the substrate SUB. The fifth gate electrode GE5 may be disposed overlapping the fifth channel region CH5 in a plan view on the substrate SUB. Accordingly, when a voltage is applied to the fourth gate electrode GE4, a current may flow through the fourth channel region CH4, and when a voltage is applied to the fifth gate electrode GE5, a current may flow through the fifth channel region CH5.

Each of the fourth gate electrode GE4 and the fifth gate electrode GE5 may include a metal or a metal nitride. Examples of the metal may include aluminum, tungsten, copper, and molybdenum. Examples of the metal nitride may include titanium nitride (TiN), tantalum nitride (TaN), and tungsten nitride (WN). These may be used alone or in combination. As another example, the gate electrode GE may include a semiconductor material such as doped polysilicon. In addition, the fourth gate electrode GE4 and the fifth gate electrode GE5 may have a single-layer structure or a multilayer structure including multiple layers.

An insulating layer IL may be disposed between the fourth channel region CH4 and the fourth gate electrode GE4. The insulating layer IL may also be disposed between the fifth channel region CH5 and the fifth gate electrode GE5. The insulating layer IL may be disposed on the substrate SUB. For example, the insulating layer IL may include silicon oxide (e.g., SiO₂), silicon nitride, or a high dielectric constant insulating material. The high dielectric constant material may refer to a dielectric material having a dielectric constant greater than that of silicon oxide. Examples of such materials may include aluminum oxide (Al₂O₃), tantalum oxide (Ta₂O₅), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). These may be used alone or in combination. However, embodiments are not limited thereto.

In one or more embodiments, the fourth transistor T4 and the fifth transistor T5 may share the fourth source region SA4 and the fifth drain region DA5. For example, the impurity region forming the fourth source region SA4 and the fifth drain region DA5 may simultaneously be included in both the fourth transistor T4 and the fifth transistor T5. Accordingly, the initialization voltage (e.g., the initialization voltage VINT of FIG. 3) applied to the fourth drain region DA4 of the fourth transistor T4 may be transmitted to the fifth source region SA5 of the fifth transistor T5.

As a result, since the fourth transistor T4 and the fifth transistor T5 are disposed as NMOS transistors, an overall size may be reduced, and an integration density of transistors may be increased. Furthermore, by sharing the impurity region between the fourth source region SA4 of the fourth transistor T4 and the fifth drain region DA5 of the fifth transistor T5, an efficiency of the transistor array of the display device DD may be increased. Accordingly, display quality of the display device DD may be improved as the display device DD has a high resolution and improved.

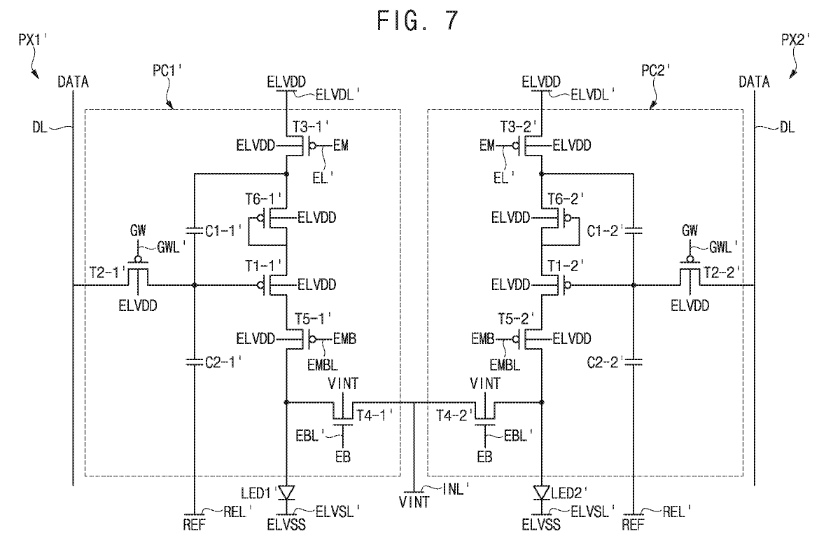

FIG. 7 is a circuit diagram of the pixel included of FIG. 2 according to one or more other embodiments. For example, circuit connections of the first pixel circuit part PC1’ and the second pixel circuit part PC2’ shown in FIG. 7 may be substantially same as circuit connections of one of the pixel circuit parts PC shown in FIG. 4. Also, the second pixel PX2’ may be substantially same as the first pixel PX1’ in a symmetrical relationship. Therefore, redundant descriptions may be omitted or simplified.

Referring to FIGS. 2, 4, and 7, the first pixel PX1’ may include a first light-emitting diode LED1’ and the first pixel circuit part PC1’. The second pixel PX2’ may include a second light-emitting diode LED2’ and the second pixel circuit part PC2’. For example, the first and second pixel circuit parts PC1’ and PC2’ may correspond to one of the pixel circuit parts PC shown in FIG. 3. The first and second light-emitting diodes LED1’ and LED2’ may correspond to one of the first, second, and third light-emitting diodes LED1, LED2, and LED3 shown in FIG. 3.

The first pixel circuit part PC1’ may include a first-first transistor T1-1’, a second-first transistor T2-1’, a third-first transistor T3-1’, a fourth-first transistor T4-1’, a fifth-first transistor T5-1’, a sixth-first transistor T6-1’, a first-first capacitor C1-1’ and a second-first capacitor C2-1’. The second pixel circuit part PC2’ may include a first-second transistor T1-2’, a second-second transistor T2-2’, a third-second transistor T3-2’, a fourth-second transistor T4-2’, a fifth-second transistor T5-2’, a sixth-second transistor T6-2’, a first-second capacitor C1-2’ and a second-second capacitor C2-2’.

In one or more embodiments, the first-first transistor T1-1’, the second-first transistor T2-1’, the third-first transistor T3-1’, the fifth-first transistor T5-1’, and the sixth-first transistor T6-1’ may all be PMOS transistors. The fourth-first transistor T4-1’ may be an NMOS transistor. However, embodiments are not limited thereto.

The first-first transistor T1-1’ may include a gate electrode, a first electrode, and a second electrode. The gate electrode of the first-first transistor T1-1’ may be connected to a second electrode of the second-first transistor T2-1’. The first electrode of the first-first transistor T1-1’ may be connected to a second electrode of the sixth-first transistor T6-1’. The second electrode of the first-first transistor T1-1’ may be connected to a second electrode of the fourth-first transistor T4-1’. The first-first transistor T1-1’ may supply a driving current to the first light-emitting diode LED1’ and may be referred to as a driving transistor.

The first-first transistor T1-1’ may further include a body electrode. The first power supply voltage ELVDD may be applied to the body electrode of the first-first transistor T1-1’. For example, a driving voltage line ELVDL’ receiving the first power supply voltage ELVDD may be connected to the body electrode of the first-first transistor T1-1’. As another example, a power supply other than the first power supply voltage ELVDD may be applied to the body electrode of the first-first transistor T1-1’.

The second-first transistor T2-1’ may include a gate electrode, a first electrode, and a second electrode. The gate electrode of the second-first transistor T2-1’ may be connected to a first gate signal line GWL’ receiving the first gate signal GW. The first electrode of the second-first transistor T2-1’ may be connected to one of the data lines DL receiving the data voltage DATA. The second electrode of the second-first transistor T2-1’ may be connected to the gate electrode of the first-first transistor T1-1’. The second-first transistor T2-1’ may be referred to as a data writing transistor.

The second-first transistor T2-1’ may further include a body electrode. The first power supply voltage ELVDD may be applied to the body electrode of the second-first transistor T2-1’. For example, the body electrode of the second-first transistor T2-1’ may be connected to the driving voltage line ELVDL’ receiving the first power supply voltage ELVDD. As another example, a power supply other than the first power supply voltage ELVDD may be applied to the body electrode of the second-first transistor T2-1’.

The second-first transistor T2-1’ may be turned on or off in response to the first gate signal GW. For example, when the first gate signal GW has an active level, the second-first transistor T2-1’ may be turned on. In this case, the second-first transistor T2-1’ may apply the data voltage DATA to the first-first transistor T1-1’. When the first gate signal GW has an inactive level, the second-first transistor T2-1’ may be turned off, and may block a supply of the data voltage DATA.

The third-first transistor T3-1’ may include a gate electrode, a first electrode, and a second electrode. The gate electrode of the third-first transistor T3-1’ may be connected to a first emission control line EL’ receiving a first emission control signal EM. The first electrode of the third-first transistor T3-1’ may be connected to the driving voltage line ELVDL’ receiving the first power supply voltage ELVDD. The second electrode of the third-first transistor T3-1’ may be connected to a first electrode of the sixth-first transistor T6-1’. The third-first transistor T3-1’ may be referred to as an emission control transistor.

The third-first transistor T3-1’ may further include a body electrode. The first power supply voltage ELVDD may be applied to the body electrode of the third-first transistor T3-1’. For example, the body electrode of the third-first transistor T3-1’ may be connected to the driving voltage line ELVDL’ receiving the first power supply voltage ELVDD. As another example, a power supply other than the first power supply voltage ELVDD may be applied to the body electrode of the third-first transistor T3-1’.

The third-first transistor T3-1’ may be turned on or off in response to the first emission control signal EM. For example, when the emission control signal EM has an active level, the third-first transistor T3-1’ may be turned on. In this case, the third-first transistor T3-1’ may apply the driving current generated by the first-first transistor T1-1’ to an anode electrode of the first light-emitting diode LED1’. When the emission control signal EM has an inactive level, the third-first transistor T3-1’ may be turned off and may block a supply of the driving current.

The fourth-first transistor T4-1’ may include a gate electrode, a first electrode, and a second electrode. The gate electrode of the fourth-first transistor T4-1’ may be connected to a second gate signal line EBL’ receiving the second gate signal EB. The first electrode of the fourth-first transistor T4-1’ may be connected to an initialization voltage line INL’ receiving the initialization voltage VINT. The second electrode of the fourth-first transistor T4-1’ may be connected to the second electrode of the first-first transistor T1-1’. For example, the fourth-first transistor T4-1’ may be electrically connected to the first-first transistor T1-1’. The fourth-first transistor T4-1’ may be referred to as an initialization transistor.

The fourth-first transistor T4-1’ may further include a body electrode. The initialization voltage VINT may be applied to the body electrode of the fourth-first transistor T4-1’. For example, the body electrode of the fourth-first transistor T4-1’ may be connected to the initialization voltage line INL’ receiving the initialization voltage VINT. As another example, a power supply other than the initialization voltage VINT may be applied to the body electrode.

The fourth-first transistor T4-1’ may be turned on or off in response to the second gate signal EB. For example, when the second gate signal EB has an active level, the fourth-first transistor T4-1’ may be turned on. In this case, the fourth-first transistor T4-1’ may apply the initialization voltage VINT to the first light-emitting diode LED1’. When the second gate signal EB has an inactive level, the fourth-first transistor T4-1’ may be turned off and may block a supply of the initialization voltage.

The fifth-first transistor T5-1’ may include a gate electrode, a first electrode, and a second electrode. The gate electrode of the fifth-first transistor T5-1’ may be connected to a second emission control line EMBL’ receiving a second emission control signal EMB. The first electrode of the fifth-first transistor T5-1’ may be connected to the first electrode of the first-first transistor T1-1’. The second electrode of the fifth-first transistor T5-1’ may be connected to the second electrode of the fourth-first transistor T4-1’. The fifth-first transistor T5-1’ may be referred to as an emission control transistor.

The fifth-first transistor T5-1’ may further include a body electrode. The initialization voltage VINT may be applied to the body electrode of the fifth-first transistor T5-1’. For example, the body electrode of the fifth-first transistor T5-1’ may be connected to the initialization voltage line INL’ receiving the initialization voltage VINT. As another example, a power supply other than the initialization voltage VINT may be applied to the body electrode.

The fifth-first transistor T5-1’ may be turned on or off in response to the second emission control signal EMB. For example, when the second emission control signal EMB has an active level, the fifth-first transistor T5-1’ may be turned on. In this case, the fifth-first transistor T5-1’ may apply the driving current to the first light-emitting diode LED1’. When the second emission control signal EMB has an inactive level, the fifth-first transistor T5-1’ may be turned off and may block a supply of the driving current.

The sixth-first transistor T6-1’ may include a gate electrode, a first electrode, and a second electrode. The gate electrode of the sixth-first transistor T6-1’ may be connected to the first electrode of the first-first transistor T1-1’. The first electrode of the sixth-first transistor T6-1’ may be connected to the second electrode of the third-first transistor T3-1’. The second electrode of the sixth-first transistor T6-1’ may be connected to the first electrode of the first-first transistor T1-1’. The sixth-first transistor T6-1’ may be referred to as an emission control transistor.

The sixth-first transistor T6-1’ may further include a body electrode. The first power supply voltage ELVDD may be applied to the body electrode of the sixth-first transistor T6-1’. For example, the body electrode of the sixth-first transistor T6-1’ may be connected to the driving voltage line ELVDL’. As another example, a power supply other than the first power supply voltage ELVDD may be applied to the body electrode.

The first capacitor C1-1’ may include a first electrode and a second electrode. The first electrode of the first capacitor C1-1’ may be connected to the second electrode of the third-first transistor T3-1’. The second electrode of the first capacitor C1-1’ may be connected to the gate electrode of the first-first transistor T1-1’.

The second capacitor C2-1’ may include a first electrode and a second electrode. The first electrode of the second capacitor C2-1’ may be connected to the reference voltage line REL receiving the reference voltage REF. The second electrode of the second capacitor C2-1’ may be connected to the gate electrode of the first-first transistor T1-1’.

The first light-emitting diode LED1’ may include a first electrode and a second electrode. The first electrode of the first light-emitting diode LED1’ may correspond to one of the pixel electrodes PE1, PE2, and PE3 in FIG. 3. The second electrode of the first light-emitting diode LED1’ may correspond to the common electrode CE in FIG. 3.

The first electrode of the first light-emitting diode LED1’ may be connected to the second electrode of the fourth-first transistor T4-1’. The second electrode of the first light-emitting diode LED1’ may be connected to a common voltage line ELVSL’ receiving the second power supply voltage ELVSS.

A connection relationship of the second pixel PX2’ shown in FIG. 7 may be substantially same as that of the first pixel PX1’ in a symmetrical manner. For example, the first-second transistor T1-2’ of the second pixel PX2’ may correspond to the first-first transistor T1-1’ of the first pixel PX1’. The second-second transistor T2-2’ of the second pixel PX2’ may correspond to the second-first transistor T2-1’ of the first pixel PX1’. The third-second transistor T3-2’ of the second pixel PX2’ may correspond to the third-first transistor T3-1’ of the first pixel PX1’. The fourth-second transistor T4-2’ of the second pixel PX2’ may correspond to the fourth-first transistor T4-1’ of the first pixel PX1’. The fifth-second transistor T5-2’ of the second pixel PX2’ may correspond to the fifth-first transistor T5-1’ of the first pixel PX1’. The sixth-second transistor T6-2’ of the second pixel PX2’ may correspond to the sixth-first transistor T6-1’ of the first pixel PX1’. However, embodiments are not limited thereto.

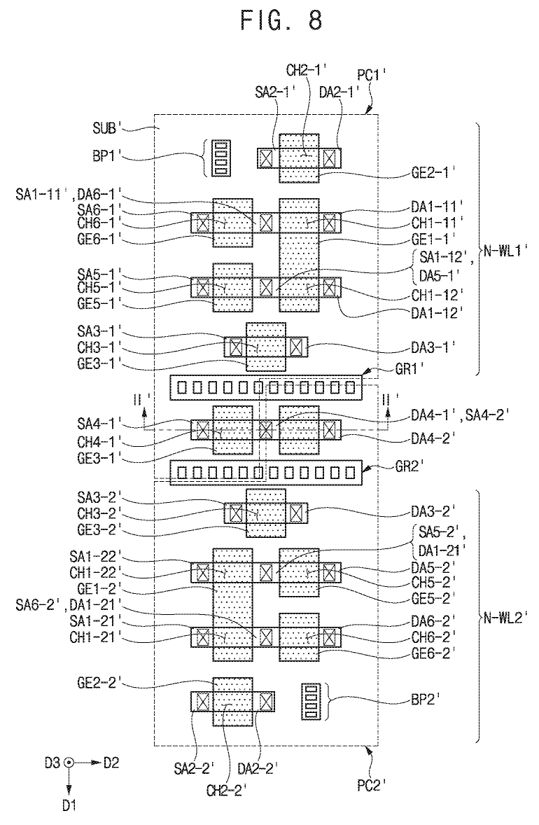

FIG. 8 is a plan view showing transistors disposed in the pixel of FIG. 7.

Referring to FIGS. 7 and 8, the substrate SUB including the first pixel PX1’ and the second pixel PX2’ may include a first N-well region N-WL1’, a second N-well region N-WL2’, and a P-well region P-WL’. For example, the first N-well region N-WL1’ and the second N-well region N-WL2’ may be spaced apart from each other in a first direction D1. The P-well region P-WL’ may be located between the first N-well region N-WL1’ and the second N-well region N-WL2’.

The fourth-first transistor T4-1’ and the fourth-second transistor T4-2’ may be disposed in the P-well region P-WL’. The first-first transistor T1-1’, the second-first transistor T2-1’, the third-first transistor T3-1’, the fifth-first transistor T5-1’, the sixth-first transistor T6-1’, and a first body pattern BP1’ may be disposed in first N-well region N-WL1’. The first-second transistor T1-2’, the second-second transistor T2-2’, the third-second transistor T3-2’, the fifth-second transistor T5-2’, the sixth-second transistor T6-2’, and a second body pattern BP2’ in the second N-well region N-WL2’.

The fourth-first transistor T4-1’ may include a fourth-first drain region DA4-1’, a fourth-first source region SA4-1’, a fourth-first channel region CH4-1’, and a fourth-first gate electrode GE4-1’. The fourth-first drain region DA4-1’ and the fourth-first source region SA4-1’ may respectively correspond to the first and second electrodes of the fourth-first transistor T4-1’ shown in FIG. 7, and the fourth-first gate electrode GE4-1’ may correspond to the gate electrode of the fourth-first transistor T4-1’ shown in FIG. 7. The fourth-first drain region DA4-1’ and the fourth-first source region SA4-1’ may be doped with an N-type material, i.e., the fourth-first transistor T4-1’ may be an NMOS transistor.

The fourth-second transistor T4-2’ may include a fourth-second drain region DA4-2’, a fourth-second source region SA4-2’, a fourth-second channel region CH4-2’, and a fourth-second gate electrode GE4-2’. The fourth-second drain region DA4-2’ and the fourth-second source region SA4-2’ may respectively correspond to the first electrode and the second electrode of the fourth-second transistor T4-2’ shown in FIG. 7, and the fourth-second gate electrode GE4-2’ of the fourth-second transistor T4-2’ may correspond to the gate electrode of the fourth-second transistor T4-2’ shown in FIG. 7. The fourth-second drain region DA4-2’ and the fourth-second source region SA4-2’ may be doped with an N-type material. For example, the fourth-second drain region DA4-2’ and the fourth-second source region SA4-2’ may be doped with an N-type material, and the fourth-second transistor T4-2’ may be an NMOS transistor.

In one or more embodiments, the drain region of the fourth-first transistor T4-1’ and the source region of the fourth-second transistor T4-2’ may be shared. For example, the drain region of the fourth-first transistor T4-1’ and the source region of the fourth-second transistor T4-2’ may refer to a same area. Accordingly, the drain region of the fourth-first transistor T4-1’ and the source region of the fourth-second transistor T4-2’ may share impurity area and may be integrally formed in the second direction D2. However, embodiments are not limited thereto.

The first-first transistor T1-1’ may include a first-eleven drain region DA1-11’, a first-eleven source region SA1-11, a first-twelve drain region DA1-12’, a first-twelve source region SA1-12, a first-eleven channel region CH1-11’, a first-twelve channel region CH1-12’, and a first-first gate electrode GE1-1’. The first-eleven drain region DA1-11’ and the first-twelve drain region DA1-12’ may correspond to the first electrode of the first-first transistor T1-1’ shown in FIG. 7. The first-eleven source region SA1-11 and the first-twelve source region SA1-12 may correspond to the second electrode of the first-first transistor T1-1’ shown in FIG. 7. The first-first gate electrode GE1-1’ may correspond to the gate electrode of the first-first transistor T1-1’ shown in FIG. 7.

The first-eleven drain region DA1-11’, the first-eleven source region SA1-11, the first-twelve drain region DA1-12’, and the first-twelve source region SA1-12 may be doped with a P-type material. For example, the first-eleven drain region DA1-11’, the first-eleven source region SA1-11, the first-twelve drain region DA1-12’, and the first-twelve source region SA1-12 may be doped with a P-type material, and the first-first transistor T1-1’ may be a PMOS transistor.

The second-first transistor T2-1’ may include a second-first drain region DA2-1’, a second-first source region SA2-1’, a second-first channel region CH2-1’, and a second-first gate electrode GE2-1’. The second-first drain region DA2-1’ and the second-first source region SA2-1’ may respectively correspond to the first electrode and the second electrode of the second-first transistor T2-1’ shown in FIG. 7, and the second-first gate electrode GE2-1’ may correspond to the gate electrode of the second-first transistor T2-1’ shown in FIG. 7. The second-first drain region DA2-1’ and the second-first source region SA2-1’ may be doped with a P-type material. For example, the second-first drain region DA2-1’ and the second-first source region SA2-1’ may be doped with a P-type material, and the second-first transistor T2-1’ may be a PMOS transistor.

The first body pattern BP1’ may be a pattern to which the first power voltage (e.g., the first power voltage ELVDD shown in FIG. 7) is applied. The first power voltage ELVDD may be applied to the first N-well region N-WL1’ of the substrate SUB through the first body pattern BP1’.

In one or more embodiments, the first body pattern BP1’ may be disposed spaced apart from the second-first transistor T2-1’ in the second direction D2. Since the first body pattern BP1’ is disposed adjacent to the second-first transistor T2-1’, the transistor array may be more efficiently arranged.

The third-first transistor T3-1’ may include a third-first drain region DA3-1’, a third-first source region SA3-1’, a third-first channel region CH3-1’, and a third-first gate electrode GE3-1’. The third-first drain region DA3-1’ and the third-first source region SA3-1’ may correspond to the first electrode and the second electrode of the third-first transistor T3-1’ shown in FIG. 7, respectively. The third-first gate electrode GE3-1’ may correspond to the gate electrode of the third-first transistor T3-1’ shown in FIG. 7.

The third-first drain region DA3-1’ and the third-first source region SA3-1’ may be doped with a P-type material. For example, the third-first drain region DA3-1’ and the third-first source region SA3-1’ may be doped with a P-type material, and the third-first transistor T3-1’ may be a PMOS transistor.

The fifth-first transistor T5-1’ may include a fifth-first drain region DA5-1’, a fifth-first source region SA5-1’, a fifth-first channel region CH5-1’, and a fifth-first gate electrode GE5-1’. The fifth-first drain region DA5-1’ and the fifth-first source region SA5-1’ may correspond to the first electrode and the second electrode of the fifth-first transistor T5-1’ shown in FIG. 7, respectively. The fifth-first gate electrode GE5-1’ may correspond to the gate electrode of the fifth-first transistor T5-1’ shown in FIG. 7.

The fifth-first drain region DA5-1’ and the fifth-first source region SA5-1’ may be doped with a P-type material. For example, the fifth-first drain region DA5-1’ and the fifth-first source region SA5-1’ may be doped with a P-type material, and the fifth-first transistor T5-1’ may be a PMOS transistor.

In one or more embodiments, the first-eleven source region SA1-11 of the first-first transistor T1-1’ and the fifth-first drain region DA5-1’ of the fifth-first transistor T5-1’ may be shared with each other. For example, the first-eleven source region SA1-11 and the fifth-first drain region DA5-1’ may refer to a same region. Accordingly, the first-first transistor T1-1’ and the fifth-first transistor T5-1’ may share an impurity region and may be integrally formed along the second direction D2.

The sixth-first transistor T6-1’ may include a sixth-first drain region DA6-1’, a sixth-first source region SA6-1’, a sixth-first channel region CH6-1’, and a sixth-first gate electrode GE6-1’. The sixth-first drain region DA6-1’ and the sixth-first source region SA6-1’ may correspond to the first electrode and the second electrode of the sixth-first transistor T6-1’ shown in FIG. 7, respectively. The sixth-first gate electrode GE6-1’ may correspond to the gate electrode of the sixth-first transistor T6-1’ shown in FIG. 7.

The sixth-first drain region DA6-1’ and the sixth-first source region SA6-1’ may be doped with a P-type material. For example, the sixth-first drain region DA6-1’ and the sixth-first source region SA6-1’ may be doped with a P-type material, and the sixth-first transistor T6-1’ may be a PMOS transistor.

In one or more embodiments, the first-twelve source region SA1-12 of the first-first transistor T1-1’ and the sixth-first drain region DA6-1’ of the sixth-first transistor T6-1’ may be shared with each other. For example, the first-twelve source region SA1-12 and the sixth-first drain region DA6-1’ may refer to a same region. Accordingly, the first-first transistor T1-1’ and the sixth-first transistor T6-1’ may share the impurity region and may be integrally formed along the second direction D2.

As a result, the first-first transistor T1-1’, the fifth-first transistor T5-1’, and the sixth-first transistor T6-1’ may have a U-shaped transistor array structure in a plan view. Accordingly, the first-first transistor T1-1’, the fifth-first transistor T5-1’, and the sixth-first transistor T6-1’ may share signals. Since the transistors share impurity regions, the transistor array layout efficiency of the display device DD may be improved.

In one or more embodiments, a first guard ring GR1’ extending in the second direction D2 may be further disposed between the first N-well region N-WL1’ and the P-well region P-WL’. The first guard ring GR1’ may serve as a reference line separating the P-well region P-WL’ and the first N-well region N-WL1’.

In addition, a second guard ring GR2’ extending in the second direction D2 may be further disposed between the second N-well region N-WL2’ and the P-well region P-WL’. The second guard ring GR2’ may serve as a reference line separating the P-well region P-WL’ and the second N-well region N-WL2’.

An arrangement of the first-second to sixth-second transistors T1-2’, T2-2’, T3-2’, T4-2’, T5-2’, and T6-2’, the first-second and second-second capacitors C1-2’ and C2-2’, and the second body pattern BP2’ disposed in the second N-well region N-WL2’ may have a point-symmetrical structure in a plan view with respect to an arrangement of the first-first to sixth-first transistors T1-1’, T2-1’, T3-1’, T4-1’, T5-1’, and T6-1’, the first-first and second-first capacitors C1-1’ and C2-1’, and the first body pattern BP1’ disposed in the first N-well region N-WL1’. Accordingly, the arrangement and connection relationship of the first-second to sixth-second transistors T1-2’, T2-2’, T3-2’, T4-2’, T5-2’, and T6-2’, the first-second and second-second capacitors C1-2’ and C2-2’, and the second body pattern BP2’ disposed in the second N-well region N-WL2’ may be substantially same to the arrangement and connection relationship of the first-first to sixth-first transistors T1-1’, T2-1’, T3-1’, T4-1’, T5-1’, and T6-1’, the first-first and second-first capacitors C1-1’ and C2-1’, and the first body pattern BP1’ disposed in the first N-well region N-WL1’. Accordingly, redundant descriptions may be omitted or simplified. However, embodiments are not limited thereto.

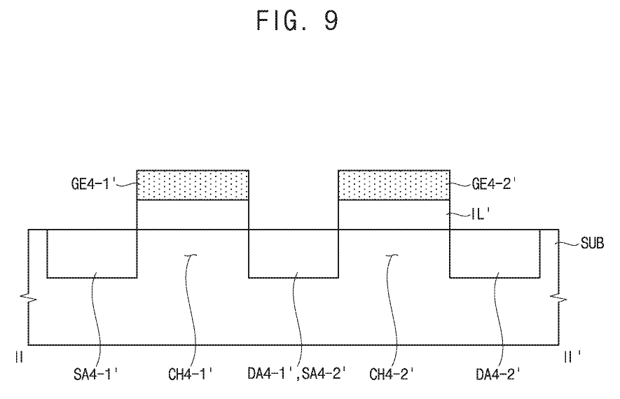

FIG. 9 is a cross-sectional view taken along line II-II’ of FIG. 8.

Referring to FIGS. 8 and 9, the fourth-first transistor T4-1’ may include the fourth-first drain region DA4-1’, the fourth-first source region SA4-1’, the fourth-first channel region CH4-1’, and the fourth-first gate electrode GE4-1’. The fourth-second transistor T4-2’ may include the fourth-second drain region DA4-2’, the fourth-second source region SA4-2’, the fourth-second channel region CH4-2’, and the fourth-second gate electrode GE4-2’.

The fourth-first channel region CH4-1’ may be defined in the substrate SUB between the fourth-first source region SA4-1’ and the fourth-first drain region DA4-1’. The fourth-second channel region CH4-2’ may be defined in the substrate SUB between the fourth-second source region SA4-2’ and the fourth-second drain region DA4-2’. A current may flow between the fourth-first drain region DA4-1’ and the fourth-first source region SA4-1’ through the fourth-first channel region CH4-1’, and a current may flow between the fourth-second drain region DA4-2’ and the fourth-second source region SA4-2’ through the fourth-second channel region CH4-2’.

In one or more embodiments, the fourth-first transistor T4-1’ and the fourth-second transistor T4-2’ may share the fourth-first drain region DA4-1’ and the fourth-second source region SA4-2’. For example, an impurity region forming the fourth-first drain region DA4-1’ and the fourth-second source region SA4-2’ may be simultaneously included in both the fourth-first transistor T4-1’ and the fourth-second transistor T4-2’. Accordingly, the initialization voltage (e.g., the initialization voltage VINT in FIG. 7) applied to the fourth-first drain region DA4-1’ of the fourth-first transistor T4-1’ may be transmitted to the fourth-first source region SA4-1’ of the fourth-second transistor T4-2’.

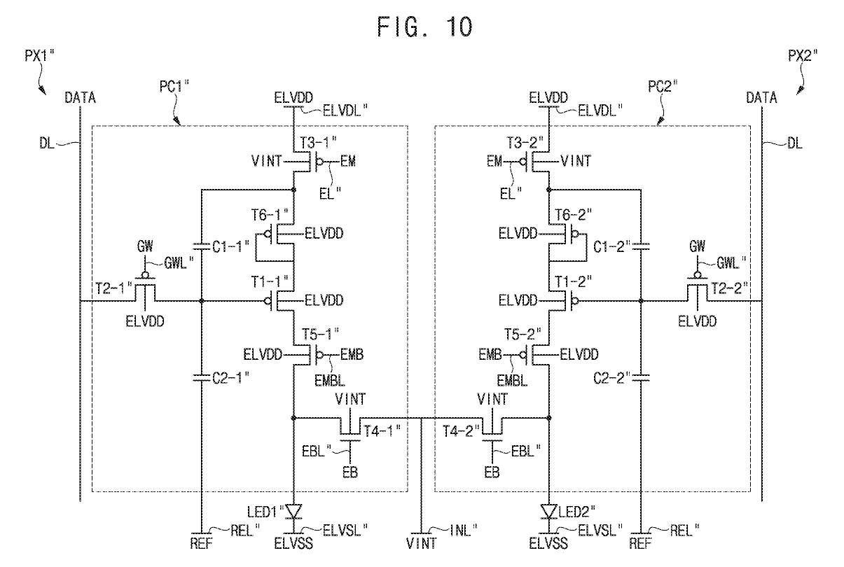

FIG. 10 is a circuit diagram showing still another embodiment of the pixel included of FIG. 2. Specifically, circuit connection relationships of the first pixel PX1’’ and the second pixel PX2’’ shown in FIG. 10 may be substantially same as circuit connection relationships of the first pixel PX1’ and the second pixel PX2’ shown in FIG. 7. Therefore, redundant content may be omitted or simplified.

Referring to FIGS. 2, 7, and 10, the first pixel PX1’’ may include a first light-emitting diode LED1’’ and a first pixel circuit part PC1’’. The second pixel PX2’’ may include a second light-emitting diode LED2’’ and a second pixel circuit part PC2’’. For example, the first pixel circuit part PC1’’ and the second pixel circuit part PC2’’ may correspond to one of the pixel circuit parts PC shown in FIG. 3. The first light-emitting diode LED1’’ and the second light-emitting diode LED2’’ may correspond to one of the first, second, and third light-emitting diodes LED1, LED2, and LED3 shown in FIG. 3.

The first pixel circuit part PC1’’ may include a first-first transistor T1-1”, a second-first transistor T2-1”, a third-first transistor T3-1”, a fourth-first transistor T4-1”, a fifth-first transistor T5-1”, a sixth-first transistor and T6-1’’, a first-first capacitor C1-1” and a second-first capacitor C2-1’’. The second pixel circuit part PC2’’ may include a first-second transistor T1-2”, a second-second transistor T2-2”, a third-second transistor T3-2”, a fourth-second transistor T4-2”, a fifth-second transistor T5-2”, a sixth-second transistor T6-2’’, a first-second capacitor C1-2”, and a second-second capacitor C2-2’’.

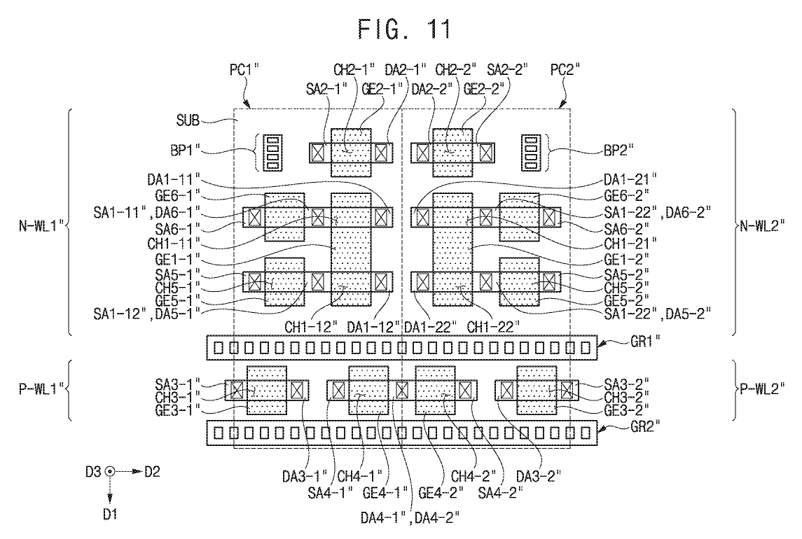

FIG. 11 is a plan view showing transistors disposed in the pixel of FIG. 10.

Referring to FIGS. 10 and 11, the substrate SUB including the first pixel PX1’’ and the second pixel PX2’’ may include a first N-well region N-WL1’’, a second N-well region N-WL2’’, a first P-well region P-WL1’’, and a second P-well region P-WL2’’. For example, the first pixel PX1’’ may include the first N-well region N-WL1’’ and the first P-well region P-WL1’’, and the second pixel PX2’’ may include the second N-well region N-WL2’’ and the second P-well region P-WL2’’.

For example, the first pixel PX1’’ and the second pixel PX2’’ may be disposed adjacent to each other in the second direction D2. The first N-well region N-WL1’’ and the first P-well region P-WL1’’ may be spaced apart from each other in the first direction D1. The second N-well region N-WL2’’ and the second P-well region P-WL2’’ may be spaced apart from each other in the first direction D1.

The first pixel PX1’’ and the second pixel PX2’’ disposed in FIG. 11 may have a symmetrical structure. Therefore, redundant contents between the first pixel PX1’’ and the second pixel PX2’’ may be omitted or simplified.

The third-first transistor T3-1’’ and the fourth-first transistor T4-1’’ may be disposed in the first P-well region P-WL1’’. The third-second transistor T3-2’’ and the fourth-second transistor T4-2’’ may be disposed in the second P-well region P-WL2’’.

The first-first transistor T1-1’’, the second-first transistor T2-1’’, the fifth-first transistor T5-1’’, the sixth-first transistor T6-1’’, and a first body pattern BP1’’ may be disposed in the first N-well region N-WL1’’. The first-second transistor T1-2’’, the second-second transistor T2-2’’, the fifth-second transistor T5-2’’, the sixth-second transistor T6-2’’, and a second body pattern BP2’’ may be disposed in the second N-well region N-WL2’’.

The fourth-first transistor T4-1’’ may include a fourth-first drain region DA4-1’’, a fourth-first source region SA4-1’’, a fourth-first channel region CH4-1’’, and a fourth-first gate electrode GE4-1’’. The fourth-first drain region DA4-1’’ and the fourth-first source region SA4-1’’ may respectively correspond to the first and second electrodes of the fourth-first transistor T4-1’’ shown in FIG. 10, and the fourth-first gate electrode GE4-1’’ may correspond to the gate electrode of the fourth-first transistor T4-1’’ shown in FIG. 10. The fourth-first drain region DA4-1’’ and the fourth-first source region SA4-1’’ may be doped with an N-type material. For example, the fourth-first transistor T4-1’’ may be an NMOS transistor.

The fourth-second transistor T4-2’’ may include a fourth-second drain region DA4-2’’, a fourth-second source region SA4-2’’, a fourth-second channel region CH4-2’’, and a fourth-second gate electrode GE4-2’’. The fourth-second drain region DA4-2’’ and the fourth-second source region SA4-2’’ may respectively correspond to the first and second electrodes of the fourth-second transistor T4-2’’ shown in FIG. 10, and the fourth-second gate electrode GE4-2’’ may correspond to the gate electrode of the fourth-second transistor T4-2’’ shown in FIG. 10. The fourth-second drain region DA4-2’’ and the fourth-second source region SA4-2’’ may be doped with an N-type material. For example, the fourth-second transistor T4-2’’ may be an NMOS transistor.

In one or more embodiments, the fourth-first drain region DA4-1’’ of the fourth-first transistor T4-1’’ and the fourth-second drain region DA4-2’’ of the fourth-second transistor T4-2’’ may be shared with each other. For example, the fourth-first drain region DA4-1’’ and the fourth-second drain region DA4-2’’ may refer to a same region. Accordingly, the fourth-first transistor T4-1’’ and the fourth-second transistor T4-2’’ may share an impurity region and may be integrally formed in the second direction D2. However, embodiments are not limited thereto.

The third-first transistor T3-1’’ may be spaced apart from the fourth-first transistor T4-1’’ in the second direction D2. The third-first transistor T3-1’’ may include a third drain region DA3-1’’, a third source region SA3-1’’, a third channel region CH3-1’’, and a third gate electrode GE3-1’’. The third drain region DA3-1’’ and the third source region SA3-1’’ may respectively correspond to the first and second electrodes of the third-first transistor T3-1’’ shown in FIG. 10, and the third gate electrode GE3-1’’ may correspond to the gate electrode of the third-first transistor T3-1’’ shown in FIG. 10. The third drain region DA3-1’’ and the third source region SA3-1’’ may be doped with an N-type material, and the third-first transistor T3-1’’ may be an NMOS transistor.

The first-first transistor T1-1’’ may include a first-eleven drain region DA1-11’’, a first-eleven source region SA1-11’’, a first-twelve drain region DA1-12’’, a first-twelve source region SA1-12’’, a first-eleven channel region CH1-11’’, a first-twelve channel region CH1-12’’, and a first-first gate electrode GE1-1’’. The first-eleven drain region DA1-11’’ and the first-twelve drain region DA1-12’’ may correspond to the first electrode of the first-first transistor T1-1’’ shown in FIG. 10. The first-eleven source region SA1-11’’ and the first-twelve source region SA1-12’’ may correspond to the second electrode of the first-first transistor T1-1’’ shown in FIG. 10. The first-first gate electrode GE1-1’’ may correspond to the gate electrode of the first-first transistor T1-1’’ shown in FIG. 10.

The first-eleven drain region DA1-11’’, the first-eleven source region SA1-11’’, the first-twelve drain region DA1-12’’, and the first-twelve source region SA1-12’’ may be doped with a P-type material. For example, the first-eleven drain region DA1-11’’, the first-eleven source region SA1-11’’, the first-twelve drain region DA1-12’’, and the first-twelve source region SA1-12’’ may be doped with a P-type material, and the first-first transistor T1-1’’ may be a PMOS transistor.

The second-first transistor T2-1’’ may include a second-first drain region DA2-1’’, a second-first source region SA2-1’’, a second-first channel region CH2-1’’, and a second-first gate electrode GE2-1’’. The second-first drain region DA2-1’’ and the second-first source region SA2-1’’ may correspond to the first and second electrodes, respectively, of the second-first transistor T2-1’’ shown in FIG. 10. The second-first gate electrode GE2-1’’ may correspond to the gate electrode of the second-first transistor T2-1’’ shown in FIG. 10. The second-first drain region DA2-1’’ and the second-first source region SA2-1’’ may be doped with a P-type material. For example, the second-first drain region DA2-1’’ and the second-first source region SA2-1’’ may be doped with a P-type material, and the second-first transistor T2-1’’ may be a PMOS transistor.

The first body pattern BP1’’ may be a pattern to which the first power supply voltage (e.g., the first power supply voltage ELVDD in FIG. 10) is applied. Through the first body pattern BP1’’, the first power supply voltage ELVDD may be applied to the first N-well region N-WL1’’ of the substrate SUB.

In one or more embodiments, the first body pattern BP1’’ may be disposed to be spaced apart from the second transistor T2-1’’ in the second direction D2. Since the first body pattern BP1’’ is disposed adjacent to the second transistor T2-1’’, the transistor array may be efficiently arranged.

The fifth transistor T5-1’’ may include a fifth drain region DA5-1’’, a fifth source region SA5-1’’, a fifth channel region CH5-1’’, and a fifth gate electrode GE5-1’’. The fifth drain region DA5-1’’ and the fifth source region SA5-1’’ may respectively correspond to the first and second electrodes of the fifth transistor T5-1’’ shown in FIG. 10, and the fifth gate electrode GE5-1’’ may correspond to the gate electrode of the fifth transistor T5-1’’ shown in FIG. 10. The fifth drain region DA5-1’’ and the fifth source region SA5-1’’ may be doped with a P-type material. For example, the fifth drain region DA5-1’’ and the fifth source region SA5-1’’ may be doped with a P-type material, and the fifth transistor T5-1’’ may be a PMOS transistor.

In one or more embodiments, the first-eleven source region SA1-11’’ of the first transistor T1-1’’ and the fifth drain region DA5-1’’ of the fifth transistor T5-1’’ may be shared. For example, the first-eleven source region SA1-11’’ and the fifth drain region DA5-1’’ may refer to a same region. Accordingly, the first transistor T1-1’’ and the fifth transistor T5-1’’ may share an impurity region and may be integrally formed in the second direction D2.

The sixth transistor T6-1’’ may include a sixth drain region DA6-1’’, a sixth source region SA6-1’’, a sixth channel region CH6-1’’, and a sixth gate electrode GE6-1’’. The sixth drain region DA6-1’’ and the sixth source region SA6-1’’ may respectively correspond to the first and second electrodes of the sixth transistor T6-1’’ shown in FIG. 10, and the sixth gate electrode GE6-1’’ may correspond to the gate electrode of the sixth transistor T6-1’’ shown in FIG. 10. The sixth drain region DA6-1’’ and the sixth source region SA6-1’’ may be doped with a P-type material. For example, the sixth drain region DA6-1’’ and the sixth source region SA6-1’’ may be doped with a P-type material, and the sixth transistor T6-1’’ may be a PMOS transistor.

In one or more embodiments, the first-twelve source region SA1-12’’ of the first transistor T1-1’’ and the sixth drain region DA6-1’’ of the sixth transistor T6-1’’ may be shared. For example, the first-twelve source region SA1-12’’ and the sixth drain region DA6-1’’ may refer to a same region. Accordingly, the first transistor T1-1’’ and the sixth transistor T6-1’’ may share the impurity region and may be integrally formed in the second direction D2.

As a result, the first transistor T1-1’’, the fifth transistor T5-1’’, and the sixth transistor T6-1’’ may have a U-shaped transistor array structure in a plan view. Accordingly, the first transistor T1-1’’, the fifth transistor T5-1’’, and the sixth transistor T6-1’’ may share signals.

In one or more embodiments, a first guard ring GR1’’ extending in the second direction D2 may be further disposed between the first N-well region N-WL1’’ and the first P-well region P-WL1’’. The first guard ring GR1’’ may be a reference line that separates the first P-well region P-WL1’’ and the first N-well region N-WL1’’. Also, a second guard ring GR2’’ may be further disposed in a region adjacent to the first direction D1 of the first N-well region N-WL1’’.

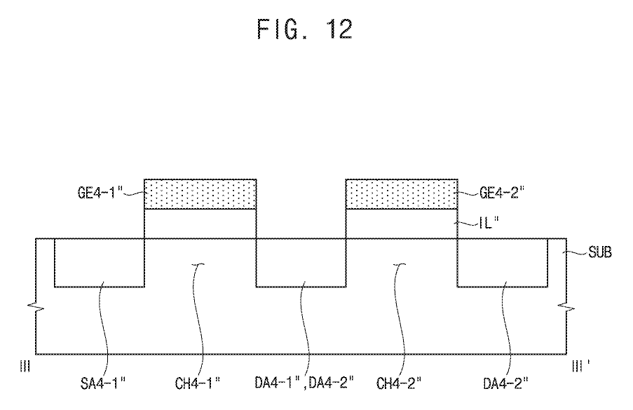

FIG. 12 is a cross-sectional view taken along line III-III’ of FIG. 11.

Referring to FIGS. 11 and 12, the fourth transistor T4-1’’ may include the fourth drain region DA4-1’’, the fourth source region SA4-1’’, the fourth channel region CH4-1’’, and the fourth gate electrode GE4-1’’. The fourth transistor T4-2’’ may include the fourth drain region DA4-2’’, the fourth source region SA4-2’’, the fourth channel region CH4-2’’, and the fourth gate electrode GE4-2’’.

The fourth channel region CH4-1’’ may be defined in the substrate SUB between the fourth source region SA4-1’’ and the fourth drain region DA4-1’’. The fourth channel region CH4-2’’ may be defined in the substrate SUB between the fourth source region SA4-2’’ and the fourth drain region DA4-2’’. A current may flow between the fourth drain region DA4-1’’ and the fourth source region SA4-1’’ through the fourth channel region CH4-1’’, and a current may flow between the fourth drain region DA4-2’’ and the fourth source region SA4-2’’ through the fourth channel region CH4-2’’.

In one or more embodiments, the fourth transistor T4-1’’ and the fourth transistor T4-2’’ may share the fourth drain region DA4-1’’ and the fourth source region SA4-2’’. For example, an impurity region forming the fourth drain region DA4-1’’ and the fourth source region SA4-2’’ may be included in both the fourth transistor T4-1’’ and the fourth transistor T4-2’’. Accordingly, the initialization voltage (e.g., the initialization voltage VINT of FIG. 7) applied to the fourth drain region DA4-1’’ of the fourth transistor T4-1’’ may be transmitted to the fourth source region SA4-2’’ of the fourth transistor T4-2’’.

As a result, as shown in FIGS. 5, 8, and 11, the fourth transistor T4 and the fourth-first transistors T4-1′, T4-1’’, to which the initialization voltage is applied, may be formed as NMOS transistors, thereby reducing a size and increasing an integration density of transistors. In addition, as the fourth transistor T4 and the fourth-first transistor sT4-1′, T4-1’’ share an impurity region with adjacent transistors, transistor array may be more efficiently arranged. Accordingly, the display device (e.g., the display device DD in FIG. 1) may implement a highly integrated transistor array and may provide relatively high-definition display quality to the user.

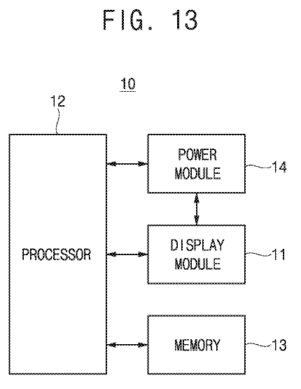

FIG. 13 is a block diagram showing an electronic device according to one or more embodiments.

Referring to FIGS. 1 and 13, the display device DD according to one or more embodiments may be applied to various electronic devices 10. An electronic device 10 according to one or more embodiments may include the display device DD and additional modules or devices providing other functionalities.

The electronic device 10 may include a display module 11, a processor 12, a memory 13, and a power module 14.

The processor 12 may include at least one of a central processing unit CPU, an application processor AP, a graphics processing unit GPU, a communication processor CP, an image signal processor ISP, and a controller.

The memory 13 may store data and information required for an operation of the processor 12 or the display module 11. When the processor 12 executes an application stored in the memory 13, video data signals and/or input control signals may be transmitted to the display module 11. The display module 11 may process the received signals to output video information on the display screen.

The power module 14 may include a power adapter, a battery device, and a power conversion module for generating the power required for an operation of the electronic device 10.

At least one component of the electronic device 10 described above may be included in the display device according to one or more embodiments. Some individual components functionally included in a module may be integrated into the display device, while others may be provided separately from the display device. For example, the display device DD may include the display module 11, while the processor 12, the memory 13, and the power module 14 may be provided as separate devices within the electronic device 10.

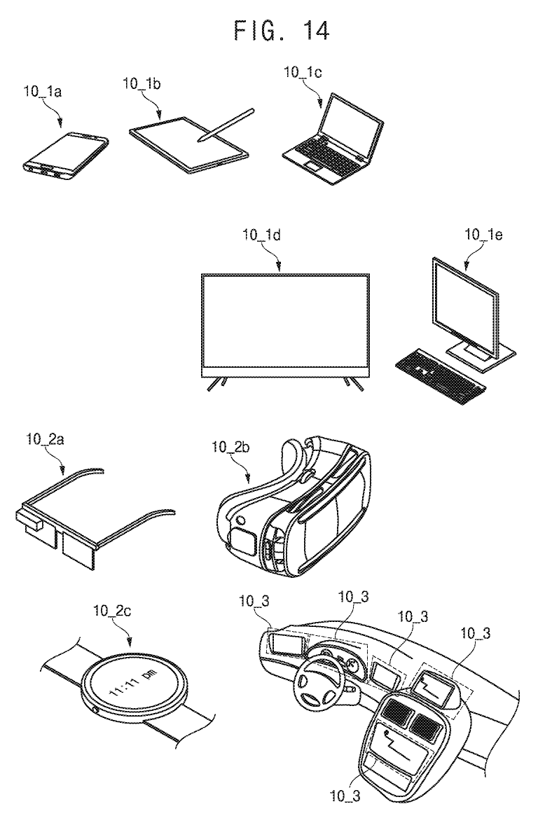

FIG. 14 is schematic diagrams of the electronic device of FIG. 13 according to one or more embodiments.

Referring to FIGS. 13 and 14, various electronic devices 10 incorporating the display device DD may include image-display electronic devices such as smartphones 10_1a, tablet PCs 10_1b, laptops 10_1c, TVs 10_1d, and desktop monitors 10_1e. In addition, wearable electronic devices including display modules, such as smart glasses 10_2a, head-mounted displays 10_2b, and smartwatches 10_2c, and vehicle electronic devices including display modules, such as instrument clusters, center information displays (CID), and room mirror displays, may also be included.

However, these examples are illustrative, and the electronic device 10 according to embodiments are not limited thereto. For example, the electronic device 10 may be implemented as a mobile phone, videophone, smart pad, smartwatch, tablet PC, vehicle display, computer monitor, laptop, or head-mounted display device. In addition, the electronic device 10 may be a television, monitor, laptop computer, or tablet. Furthermore, the electronic device 10 may also be a vehicle.

While embodiments have been described with reference to the figures, it will be understood by those of ordinary skill in the art that various changes in form and details may be made therein without departing from the spirit and scope as defined by the following claims and their equivalents.

What is claimed is:

1. A display device comprising:
a substrate comprising an N-well region and a P-well region spaced apart from the N-well region in a first direction; and
a pixel comprising:
a first transistor in the P-well region of the substrate, the first transistor comprising a first drain region configured to receive an initialization voltage and a first source region connected to a pixel electrode of a light-emitting diode;
a second transistor in the P-well region of the substrate, the second transistor comprising a second drain region sharing an impurity region with the first source region of the first transistor and a second source region connected to a driving transistor; and
a third transistor in the N-well region of the substrate, the third transistor being configured to receive a data voltage and control the driving transistor.

2. The display device of claim 1, further comprising:
a first channel region between the first drain region and the first source region; and
a second channel region between the second drain region and the second source region.

3. The display device of claim 2, wherein the first transistor further comprises a first gate electrode overlapping the first channel region in a second direction intersecting the first direction, and
wherein the second transistor further comprises a second gate electrode overlapping the second channel region in the second direction.

4. The display device of claim 1, further comprising a body pattern in the N-well region and configured to receive a power supply voltage.

5. The display device of claim 4, wherein the body pattern is spaced apart from the third transistor in a third direction intersecting the first direction.

6. The display device of claim 1, further comprising a guard ring between the P-well region and the N-well region and extending in a third direction intersecting the first direction.

7. A display device comprising:
a substrate comprising a first N-well region, a second N-well region spaced apart from the first N-well region in a first direction, and a P-well region between the first N-well region and the second N-well region;
a first pixel comprising:
a first-first transistor in the P-well region of the substrate, the first-first transistor comprising a first-first drain region configured to receive an initialization voltage and a first-first source region connected to a pixel electrode of a first light-emitting diode; and
a second-first transistor in the first N-well region of the substrate, the second-first transistor being comprising to receive a data voltage is applied and control a first driving transistor; and
a second pixel comprising:
a first-second transistor in the P-well region of the substrate, the first-second transistor comprising a first-second source region connected to a pixel electrode of a second light-emitting diode and a first-second drain region sharing an impurity region with the first-first drain region of the first-first transistor; and
a second-second transistor in the second N-well region, the second-second transistor being configured to receive a data voltage and control a second driving transistor.

8. The display device of claim 7, further comprising:
a first-first channel region between the first-first drain region and the first-first source region; and
a first-second channel region between the first-second drain region and the first-second source region.

9. The display device of claim 8, wherein the first-first transistor further comprises a first-first gate electrode overlapping the first-first channel region in a second direction intersecting the first direction, and
wherein the first-second transistor further comprises a first-second gate electrode overlapping the first-second channel region in the second direction.

10. The display device of claim 7, further comprising:
a first body pattern in the first N-well region and configured to receive a power supply voltage; and
a second body pattern in the second N-well region and configured to receive a power supply voltage.

11. The display device of claim 10, wherein the first body pattern is spaced apart from the second-first transistor in a third direction intersecting the first direction, and
wherein the second body pattern is spaced apart from the second-second transistor in the third direction.

12. The display device of claim 7, further comprising:
a first guard ring between the P-well region and the first N-well region and extending in a third direction intersecting the first direction; and
a second guard ring between the P-well region and the second N-well region and extending in the third direction.

13. An electronic device comprising:
a display device; and
a processor configured to drive the display device,
wherein the display device comprises:
a substrate comprising an N-well region and a P-well region spaced apart from the N-well region in a first direction; and
a pixel comprising:
a first transistor in the P-well region of the substrate, the first transistor comprising a first drain region configured to receive an initialization voltage and a first source region connected to a pixel electrode of a light-emitting diode;
a second transistor in the P-well region of the substrate, the second transistor comprising a second drain region sharing an impurity region with the first source region of the first transistor and a second source region connected to a driving transistor; and
a third transistor in the N-well region of the substrate, the third transistor being configured to receive a data voltage and control the driving transistor.

14. The electronic device of claim 13, further comprising a body pattern in the N-well region and configured to receive a power supply voltage, and
wherein the body pattern is spaced apart from the third transistor in a second direction intersecting the first direction.

15. The electronic device of claim 13, further comprising:
a first channel region between the first drain region and the first source region; and
a second channel region between the second drain region and the second source region.

16. The electronic device of claim 15, wherein the first transistor further comprises a first gate electrode overlapping the first channel region in a second direction intersecting the first direction, and
wherein the second transistor further comprises a second gate electrode overlapping the second channel region in the second direction.

17. The electronic device of claim 13, further comprising a first guard ring between the P-well region and the N-well region and extending in a third direction intersecting the first direction.

18. The electronic device of claim 17, further comprising a second guard ring on a side of the P-well region opposite to the first guard ring.

19. The electronic device of claim 13, further comprising a fourth transistor and a fifth transistor in the N-well region and spaced apart from the third transistor in the first direction,
wherein a drain region of the fourth transistor and a source region of the fifth transistor are shared.

20. The electronic device of claim 19, wherein the driving transistor is disposed in the N-well region and between the first transistor and the third transistor.
